(19) United States
(12) Patent Application Publication
(10) Pub. No.: US 2022/0310928 A1
(43) Pub. Date: Sep. 29, 2022

(54) DISPLAY DEVICE

(71) Applicant: Samsung Display Co., Ltd., Yongin-si (KR)

(72) Inventors: Ju Hyun LEE, Seongnam-si (KR); Gyung Min BAEK, Yongin-si (KR); Tae Wook KANG, Seongnam-si (KR); Shin Il CHOI, Hwaseong-si (KR); Do Keun SONG, Yongin-si (KR)

(21) Appl. No.: 17/648,409

(22) Filed: Jan. 19, 2022

(30) Foreign Application Priority Data
Mar. 25, 2021 (KR) 10-2021-0038644

(51) Int. Cl. H01L 51/00

(52) U.S. Cl. CPC H01L 51/0037; H01L 51/502

(57) ABSTRACT

A display device comprises first and second electrodes extending in one direction on a substrate, the first and second electrodes being spaced apart from each other, an organic layer on the first and second electrodes, the organic layer including a plurality of conductive regions and an insulating region, light-emitting elements on the organic layer and on the first and second electrodes, and a first connecting electrode coupled to first end portions of the light-emitting elements and one of the plurality of conductive regions, and a second connecting electrode coupled to second end portions of the light-emitting elements and another one of the plurality of conductive regions, wherein the organic layer includes PEDOT:PSS, and a surface roughness of the insulating region is greater than a surface roughness of the plurality of conductive regions.

### CROSS-REFERENCE TO RELATED APPLICATION

This application claims priority to and the benefit of Korean Patent Application No. 10-2021-0038644, filed on Mar. 25, 2021, in the Korean Intellectual Property Office, the entire contents of which are hereby incorporated by reference.

### BACKGROUND

### 1. Field

The present disclosure relates to a display device.

### 2. Description of the Related Art

Display devices are becoming more important with developments in multimedia technology. Accordingly, various display devices such as an organic light-emitting diode (OLED) display device, a liquid crystal display (LCD) device, and/or the like have been used.

A display device, which displays an image, may include a display panel such as an OLED display panel or an LCD panel. The display panel, particularly, a light-emitting element display panel, may include light-emitting elements. For example, light-emitting diodes (LEDs) may include OLEDs using an organic material as a light-emitting material and inorganic light-emitting diodes (ILEDs) using an inorganic material as a light-emitting material.

### SUMMARY

One or more aspects of embodiments of the present disclosure are directed toward a display device capable of improving contact characteristics by preventing or reducing a galvanic phenomenon between electrodes.

However, embodiments of the present disclosure are not restricted to those set forth herein. The above and other embodiments of the present disclosure will become more apparent to one of ordinary skill in the art to which the present disclosure pertains by referencing the detailed description of the present disclosure given below.

According to one or more embodiments of the present disclosure, the display device comprises a first electrode and a second electrode, each extending in one direction on a substrate, the first and second electrodes being spaced apart from each other, an organic layer on the first and second electrodes, the organic layer including a plurality of conductive regions and an insulating region, light-emitting elements on the organic layer and on the first and second electrodes, and a first connecting electrode connected (e.g., coupled) to first end portions of the light-emitting elements and one of the plurality of conductive regions, and a second connecting electrode connected (e.g., coupled) to second end portions of the light-emitting elements and another one of the plurality of conductive regions, wherein the organic layer includes PEDOT:PSS, and a surface roughness of the insulating region is greater than a surface roughness of the plurality of conductive regions.

In one or more embodiments, the plurality of conductive regions include a first conductive region, which overlaps with the first electrode and the first connecting electrode, and a second conductive region, which overlaps with the second electrode and the second connecting electrode.

In one or more embodiments, a first surface of the first conductive region is in contact with the first electrode, a second surface of the first conductive region is in contact with the first connecting electrode, a first surface of the second conductive region is in contact with the second electrode, and a second surface of the second conductive region is in contact with the second connecting electrode.

In one or more embodiments, the insulating region is a region of the organic layer other than the plurality of conductive regions.

In one or more embodiments, the plurality of conductive regions include a compound represented by Formula 1, and the insulating region includes a compound represented by Formula 2:

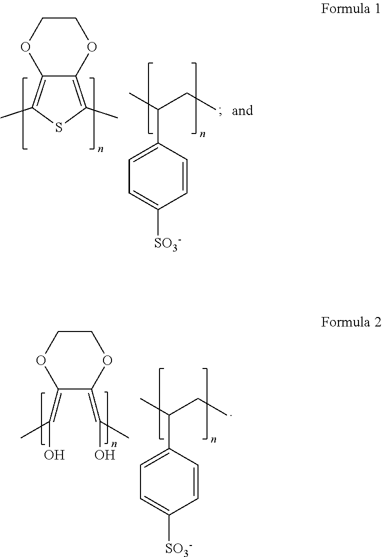

In one or more embodiments, the substrate includes a display area and a pad area, the first electrode, the second electrode, the light-emitting elements, the first connecting electrode, and the second connecting electrode are in the display area, and the organic layer is in the display area and the pad area.

In one or more embodiments, the pad area includes a pad electrode on the substrate, a pad electrode upper layer on the pad electrode, the organic layer on the pad electrode upper layer, and a pad electrode capping layer on the organic layer.

In one or more embodiments, the pad electrode upper layer includes the same material as the first electrode or the second electrode, the pad electrode capping layer includes the same material as the first connecting electrode or the second connecting electrode, and the organic layer further includes a third conductive region, which overlaps with the pad electrode upper layer.

In one or more embodiments, a first surface of the third conductive region is in contact with the pad electrode upper layer, and a second surface of the third conductive region is in contact with the pad electrode capping layer.

In one or more embodiments, the organic layer further includes conductive particles, and the conductive particles are in an amount of 1 wt % to 10 wt % with respect to 100 wt % of the organic layer.

In one or more embodiments, the conductive particles include at least one selected from among a metal, silver nanowires, and graphene.

According to one or more embodiments of the present disclosure, the display device comprises a first electrode and a second electrode, each extending in one direction on a substrate, the first and second electrodes being spaced apart from each other, an organic layer on the first and second electrodes, the organic layer including a plurality of conductive regions and an insulating region, light-emitting elements on the organic layer and on the first and second electrodes, and a first connecting electrode connected (e.g., coupled) to first end portions of the light-emitting elements and to one of the plurality of conductive regions, and a second connecting electrode connected (e.g., coupled) to second end portions of the light-emitting elements and to another one of the plurality of conductive regions, wherein the plurality of conductive regions of the organic layer include a compound represented by Formula 1, and the insulating region of the organic layer includes a compound represented by Formula 2:

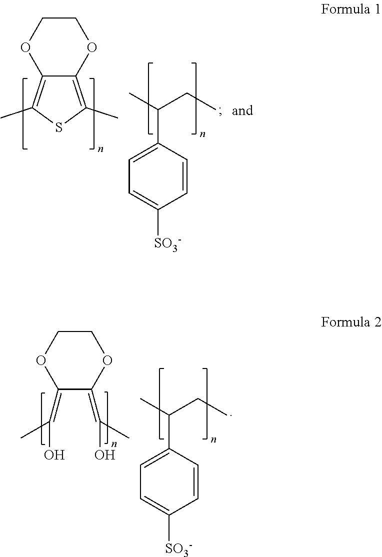

In one or more embodiments, a surface roughness of the insulating region is greater than a surface roughness of the plurality of conductive regions.

In one or more embodiments, the display device further comprises a bank on the organic layer, the bank including an emission area including the light-emitting elements, and a subarea spaced apart from the emission area.

In one or more embodiments, the plurality of conductive regions are in the emission area or the subarea.

In one or more embodiments, the plurality of conductive regions include a first conductive region, which overlaps with the first electrode and the first connecting electrode, and a second conductive region, which overlaps with the second electrode and the second connecting electrode.

In one or more embodiments, the organic layer further includes conductive particles, and the conductive particles are in an amount of 1 wt % to 10 wt % with respect to 100 wt % of the organic layer.

In one or more embodiments, the conductive particles include at least one selected from among a metal, silver nanowires, and graphene.

In one or more embodiments, the display device further comprises a first bank pattern between the substrate and the first electrode, and a second bank pattern between the substrate and the second electrode, wherein the plurality of conductive regions overlap with the first and second bank patterns.

In one or more embodiments, each of the light-emitting elements includes a first semiconductor layer doped with an n-type dopant, a second semiconductor layer doped with a p-type dopant, a light-emitting layer between the first and second semiconductor layers, and an insulating film around outer surfaces of the first semiconductor layer, the second semiconductor layer, and the light-emitting layer.

According to the aforementioned and other embodiments of the present disclosure, an organic layer is formed to cover electrodes, and conductive regions are formed in the organic layer without exposing the electrodes. Accordingly, as the organic layer protects the electrodes so that the exposure of electrodes to a developing agent and/or the like can be prevented or reduced, the occurrence of a galvanic phenomenon in the electrodes can be prevented or reduced, and an increase in the resistance between the electrodes and connecting electrodes can be prevented or reduced.

Other features and embodiments may be apparent from the following detailed description, the drawings, and the claims.

### BRIEF DESCRIPTION OF THE DRAWINGS

The above and other embodiments and features of the present disclosure will become more apparent by describing in more detail embodiments thereof with reference to the attached drawings, in which:

FIG. 1 is a plan view of a display device according to one or more embodiments of the present disclosure;

FIG. 2 is a layout view illustrating a plurality of lines of the display device of FIG. 1;

FIG. 3 is an equivalent circuit diagram of a subpixel of the display device of FIG. 1;

FIG. 4 is a plan view of a pixel of the display device of FIG. 1;

FIG. 5 is a cross-sectional view taken along line Q1-Q1′ of FIG. 4;

FIG. 6 is a cross-sectional view taken along line Q2-Q2′ of FIG. 4 and illustrates portion of a pad area of the display device of FIG. 1;

FIG. 7 is a cross-sectional view of part A of FIG. 5;

FIG. 8 is a plan view of a portion of an organic layer of the display device of FIG. 1;

FIG. 9 illustrates the chemical mechanism of the organic layer of the display device of FIG. 1;

FIG. 10 is a perspective view of a light-emitting element according to one or more embodiments of the present disclosure;

FIGS. 11-19 are cross-sectional views illustrating how to fabricate a display device according to one or more embodiments of the present disclosure;

FIG. 20 is a plan view of a subpixel of a display device according to another embodiment of the present disclosure;

FIG. 21 is a cross-sectional view taken along line Q3-Q3′ of FIG. 20;

FIG. 22 is a cross-sectional view taken along line Q4-Q4′ of FIG. 20;

FIG. 23 is a plan view of a pixel of a display device according to one or more other embodiments of the present disclosure;

FIG. 24 is a cross-sectional view taken along line Q5-Q5′ of FIG. 23;

FIG. 25 is a cross-sectional view taken along line Q6-Q6′ of FIG. 23;

FIG. 26 is an optical microscope image of sample #2;

FIG. 27 is an optical microscope image of sample #3;

FIG. 28 is an optical microscope image of sample #4;

FIG. 29 is an atomic force microscopy (AFM) image of sample #1;

FIG. 30 is a graph showing AFM measurements from sample #1;

FIG. 31 is an AFM image of sample #2;

FIG. 32 is a graph showing AFM measurements from sample #2;

FIG. 33 is a graph showing the transmittances of samples #5 and #6 in accordance with wavelength; and

FIG. 34 is a graph showing the surface resistivities of samples #5 and #6.

### DETAILED DESCRIPTION

The present disclosure will now be described more fully hereinafter with reference to the accompanying drawings, in which embodiments of the present disclosure are shown. This present disclosure may, however, be embodied in different forms and should not be construed as limited to the embodiments set forth herein. Rather, these embodiments are provided so that this disclosure will be thorough and complete, and will filly convey the scope of the disclosure to those skilled in the art.

It will also be understood that when a layer is referred to as being “on” another layer or substrate, it can be directly on the other layer or substrate (without any intervening layers therebetween), or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

As used herein, expressions such as “at least one of”, “one of”, and “selected from”, when preceding a list of elements, modify the entire list of elements and do not modify the individual elements of the list.

As used herein, the term “and/or” includes any and all combinations of one or more of the associated listed items.

Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Embodiments of the present disclosure will hereinafter be described with reference to the accompanying drawings.

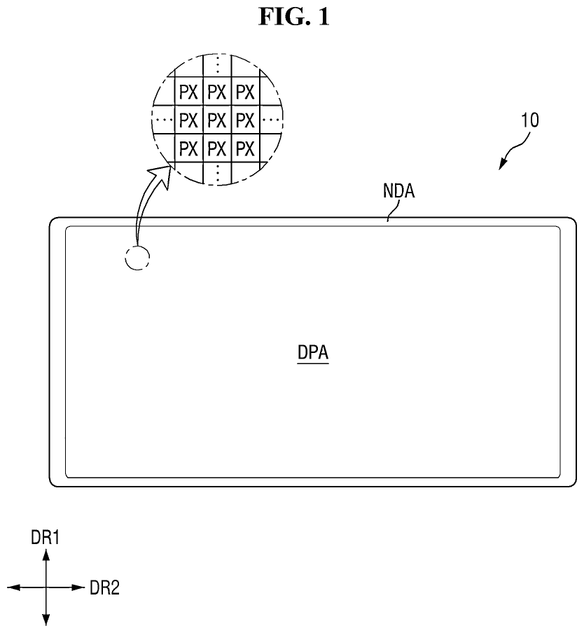

FIG. 1 is a plan view of a display device according to one or more embodiments of the present disclosure.

Referring to FIG. 1, a display device 10 displays a moving and/or still image. The display device 10 may refer to all suitable types (or kinds) of electronic devices that provide a display screen. Examples of the display device 10 may include a television (TV), a notebook computer, a monitor, a billboard, an Internet-of-Things (IoT) device, a mobile phone, a smartphone, a tablet personal computer (PC), an electronic watch, a smartwatch, a watchphone, a head-mounted display, a mobile communication terminal, an electronic notepad, an electronic book, a portable multimedia player (PMP), a navigation device, a gaming console, a digital camera, and a camcorder.

The display device 10 may include a display panel that provides a display screen. Examples of the display panel may include an inorganic light-emitting diode (ILED) display panel, an organic light-emitting diode (OLED) display panel, a quantum-dot light-emitting diode (QLED) display panel, a plasma display panel (PDP), and a field emission display (FED) panel. The display panel of the display device 10 will hereinafter be described as being an ILED display panel, but the present disclosure is not limited thereto.

The shape of the display device 10 may suitably vary. In one example, the display device 10 may have a rectangular shape that extends longer in a horizontal direction than in a vertical direction, a rectangular shape that extends longer in the vertical direction than in the horizontal direction, a square shape, a rectangular shape with rounded corners, another polygonal shape, and/or a circular shape. A display area DPA of the display device 10 may have a similar shape to that of the display device 10. FIG. 1 illustrates that the display device 10 and the display area DPA both have a rectangular shape that extends longer in a second direction DR2 than in a first direction DR1.

The display device 10 may include the display area DPA and a non-display area NDA. The display area DPA is an area in which a screen (e.g., an image) is displayed, and the non-display area NDA is an area in which a screen (e.g., an image) is not displayed. The display area DPA may also be referred to as an active area, and the non-display area NDA may also be referred to as an inactive area. The display area DPA may generally account for a middle portion of the display device 10.

The display area DPA may include a plurality of pixels PX. The pixels PX may be arranged in row and column directions. The pixels PX may have a rectangular or square shape in a plan view, but the present disclosure is not limited thereto. In one or more embodiments, the pixels PX may have a rhombus shape that is inclined with respect to a particular direction. The pixels PX may be arranged in a stripe fashion or a PenTile®/PENTILE® fashion (e.g., an RGBG matrix, RGBG structure, or RGBG matrix structure). PENTILE® is a duly registered trademark owned by Samsung Display Co., Ltd. Each of the pixels PX may include one or more light-emitting elements 30 that emit light of a particular wavelength range to emit light of a predetermined (or set) color.

The non-display area NDA may be on the periphery of the display area DPA. The non-display area NDA may surround the entire display area DPA or a portion of the display area DPA. The display area DPA may have a rectangular shape, and the non-display area NDA may be adjacent to the four sides of the display area DPA. The non-display area NDA may form the bezel of the display device 10. Wires and/or circuit drivers included in the display device 10 may be in the non-display area NDA, and/or external devices may be mounted in the non-display area NDA.

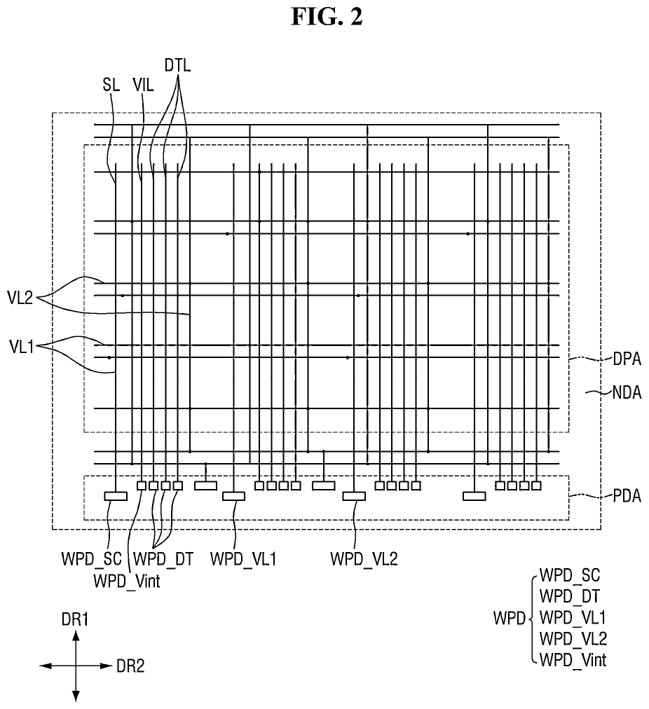

FIG. 2 is a layout view illustrating a plurality of lines of the display device of FIG. 1.

Referring to FIG. 2, the display device 10 may include a plurality of lines. The lines may include a plurality of scan lines SL, a plurality of data lines DTL, initialization voltage lines VIL, and a plurality of voltage lines VL. Also, although not specifically illustrated, the display device 10 may further include other lines.

The scan lines SL may extend in the first direction DR1. The scan lines SL may be connected (e.g., electrically and/or physically coupled) to scan line pads WPD_SC, which are connected (e.g., electrically and/or physically coupled) to a scan driver. The scan lines SL may extend from a pad area PDA, which is in the non-display area NDA, to the display area DPA, but the present disclosure is not limited thereto. The scan lines SL may extend in the second direction DR2.

Meanwhile, the term “connect” or “connection”, as used herein, not only means that one element may be directly or physically connected (or coupled) to another element, but also means that one element may be connected (or coupled) to another element via yet another element. Also, portions of a single element may be understood as being connected to one another. Also, the term “connect” or “connection”, as used herein, not only means that one element may be in physical contact with another element, but also that one element may be electrically connected (e.g., electrically coupled) to another element via yet another element.

The data lines DTL may extend in the first direction DR1. Every three data lines DTL may form a group and may be adjacent to one another. The data lines DTL may extend from the pad area PDA, which is provided in the non-display area NDA, to the display area DPA.

The initialization voltage lines VIL may extend in the first direction DR1. The initialization voltage lines VIL may be between the data lines DTL and the scan lines SL. The initialization voltage lines VIL may extend from the pad area PDA, which is provided in the non-display area NDA, may extend even into the display area DPA.

The first voltage lines VL1 and the second voltage lines VL2 may include parts that extend in the first direction DR1 and parts that extend in the second direction DR2. Portions of each of the first voltage lines VL1 and/or of each of the second voltage lines VL2 may extend across the display area DPA along the first direction DR1, and portions of each of the first voltage lines VL1 and/or of each of the second voltage lines VL2 that extend in the second direction DR2 may be in part in the display area DPA and in part in the non-display area NDA on both sides, in the first direction DR1, of the display area DPA. The first voltage lines VL1 and the second voltage lines VL2 may form a mesh structure over the entire surface of the display area DPA.

The scan lines SL, the data lines DTL, the initialization voltage lines VIL, the first voltage lines VL1, and the second voltage lines VL2 may be electrically connected (e.g., electrically coupled) to one or more wire pads WPD. The wire pads WPD may be in the non-display area NDA. The wire pads WPD may be in the pad area PDA on a second side, in the first direction DR1, of the display area DPA (e.g., on a lower side of the display area DPA), but the location of the pad area PDA may vary depending on the size and/or the specification of the display device 10. The scan lines SL may be connected (e.g., electrically and/or physically coupled) to the scan line pads WPD_SC, which are in the pad area PDA, and the data lines DTL may be connected (e.g., electrically and/or physically coupled) to different data line pads WPD_DT. The initialization voltage lines VIL may be connected to initialization line pads WPD_Vint, the first voltage lines VL1 may be connected to first voltage line pads WPD_VL1, and the second voltage lines VL2 may be connected to second voltage line pads WPD_VL2. External devices may be mounted on line pads WPD. The external devices may be mounted on the line pads WPD via anisotropic conductive films and/or through ultrasonic bonding. The line pads WPD are illustrated as being in the pad area PDA on the lower side of the display area DPA, but the present disclosure is not limited thereto. In one or more embodiments, some of the line pads WPD may be on the upper side of the display area DPA and/or on the left and/or right side of the display area DPA.

Pixels PX or subpixels SPXn (where n is an integer of 1 to 3) of the display device 10 may include pixel driving circuits. Lines may be provided to pass through or pass by the pixels PX or the subpixels SPXn of the display device 10 and apply driving signals to the pixel driving circuits. Each of the pixel driving circuits may include transistors and capacitors. The numbers of transistors and capacitors included in each of the pixel driving circuits may suitably vary. In one or more embodiments, the pixel driving circuits may have a “3T1C” structure including three transistors and one capacitor. The pixel driving circuits will hereinafter be described as having the “3T1C” structure, but the present disclosure is not limited thereto. In one or more embodiments, various other suitable structures, such as a “2T1C”, “7T1C”, or “6T1C” structure, may also be applicable to the pixel driving circuits.

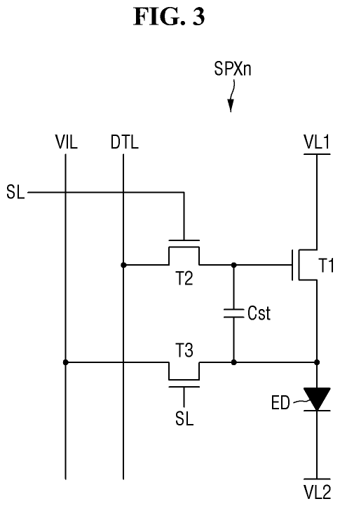

FIG. 3 is an equivalent circuit diagram of a subpixel of the display device of FIG. 1.

Referring to FIG. 3, a subpixel SPXn may include a light-emitting diode (LED) “ED”, three transistors, i.e., first, second, and third transistors T1, T2, and T3, and one storage capacitor Cst.

The LED “ED” may emit light in accordance with a current applied thereto via the first transistor T1. The LED “ED” may include a first electrode, a second electrode, and at least one light-emitting element between the first and second electrodes. The light-emitting element may emit light of a particular wavelength range in accordance with electrical signals transmitted thereto from first and second electrodes, which are connected to both ends of the LED “ED”.

A first end of the LED “ED” may be connected (e.g., electrically and/or physically coupled) to the source electrode of the first transistor T1, and a second end of the LED “ED” may be connected (e.g., electrically and/or physically coupled) to a second voltage line VL2, to which a low-potential voltage (hereinafter, a second power supply voltage) lower than a high-potential voltage (hereinafter, a first power supply voltage) is supplied. Also, a second end of the LED “ED” may be connected (e.g., electrically and/or physically coupled) to the source electrode of the second transistor T2.

The first transistor T1 controls a current flowing from the first voltage line VL1, to which the first power supply voltage is supplied, to the LED “ED” in accordance with the difference in voltage between the gate electrode and the source electrode of the first transistor T1. In one example, the first transistor T1 may be a transistor for driving the LED “ED”. The gate electrode of the first transistor T1 may be connected (e.g., electrically and/or physically coupled) to the source electrode of the second transistor T2, the source electrode of the first transistor T1 may be connected (e.g., electrically and/or physically coupled) to the first electrode of the LED “ED”, and the drain electrode of the first transistor T1 may be connected (e.g., electrically and/or physically coupled) to the first voltage line VL1, to which the first power supply voltage is supplied.

The second transistor T2 is turned on by a first scan signal from a scan line SL to connect a data line DTL to the gate electrode of the first transistor T1. The gate electrode of the second transistor T2 may be connected (e.g., electrically and/or physically coupled) to the scan line SL, the source electrode of the second transistor T2 may be connected (e.g., electrically and/or physically coupled) to the gate electrode of the first transistor T1, and the drain electrode of the second transistor T2 may be connected (e.g., electrically and/or physically coupled) to the data line DTL.

The third transistor T3 is turned on by a scan signal from a second scan line SL2 to connect an initialization voltage line VIL to a first end of the LED “ED”. The gate electrode of the third transistor T3 may be connected (e.g., electrically and/or physically coupled) to the second scan line SL2, the drain electrode of the third transistor T3 may be connected (e.g., electrically and/or physically coupled) to the initialization voltage line VIL, and the source electrode of the third transistor T3 may be connected (e.g., electrically and/or physically coupled) to the first end of the LED “EL” or the source electrode of the first transistor T1. The second and third transistors T2 and T3 may be turned on by the same scan signal.

The source electrodes and the drain electrodes of the first, second, and third transistors T1, T2, and T3 are not limited to the above descriptions. The driving transistor and the first, second, and third transistors T1, T2, and T3 may be formed as thin-film transistors (TFTs). FIG. 3 illustrates that the first, second, and third transistors T1, T2, and T3 are formed as N-type metal-oxide semiconductor field-effect transistors (MOSFETs), but the present disclosure is not limited thereto. For example, the first, second, and third transistors T1, T2, and T3 may all be formed as P-type MOSFETs. In some embodiments, some of the first, second, and third transistors T1, T2, and T3 may be formed as N-type MOSFETS, and others of the first, second, and third transistor(s) T1, T2, and T3 may be formed as P-type MOSFETs.

The storage capacitor Cst is formed between the gate electrode and the source electrode of the first transistor T1. The storage capacitor Cst stores a differential voltage corresponding to the difference in voltage between the gate electrode and the source electrode of the first transistor T1.

The structure of a pixel PX of the display device 10 will hereinafter be described in further detail.

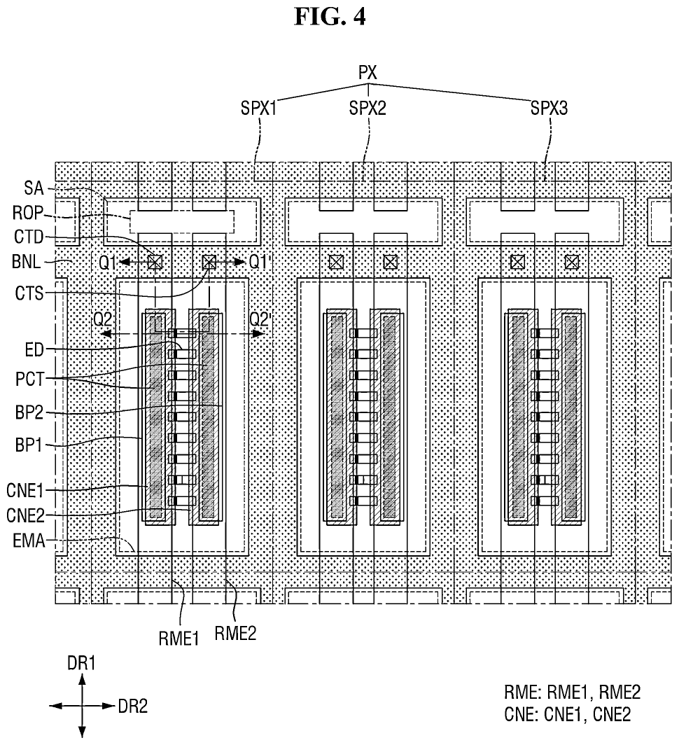

FIG. 4 is a plan view of a pixel of the display device of FIG. 1.

Referring to FIG. 4, a pixel PX may include a plurality of subpixels SPXn (where n is an integer of 1 to 3). In one or more embodiments, the pixel PX may include first, second, and third subpixels SPX1, SPX2, and SPX3. The first subpixel SPX1 may emit first-color light, the second subpixel SPX2 may emit second-color light, and the third subpixel SPX3 may emit third-color light. In one or more embodiments, the first-color light, the second-color light, and the third-color light may be blue light, green light, and red light, respectively, but the present disclosure is not limited thereto. In one or more embodiments, the subpixels SPXn may all emit light of the same color. FIG. 4 illustrates that the pixel PX may include three subpixels SPXn, but the present disclosure is not limited thereto. For example, the pixel PX may include more than three subpixels SPXn.

Each of the subpixels SPXn may include an emission area EMA and a non-emission area. The emission area EMA may be an area that outputs light of a particular or set wavelength range due to light-emitting elements ED being positioned therein, and the non-emission area may be an area which has no light-emitting elements ED therein, is not reached by light emitted by light-emitting elements ED, and thus does not output light. The emission area EMA may include a region where the light-emitting elements ED are provided, and a region around the light-emitting elements ED where light emitted by the light-emitting elements ED is output.

However, the present disclosure is not limited to this. The emission area EMA may also include regions that output light emitted by the light-emitting elements ED and then reflected and/or refracted by other members. A plurality of light-emitting elements ED may be provided in each of the subpixels SPXn to form an emission area EMA including a region in which the plurality of light-emitting elements ED are positioned and the surroundings of the region in which the plurality of light-emitting elements ED are positioned.

FIG. 4 illustrates that the emission areas EMA of the first, second, and third subpixels SPX1, SPX2, and SPX3 have the same size, but the present disclosure is not limited thereto. In some embodiments, the emission areas EMA of the subpixels SPXn may have different sizes depending on the color and/or the wavelength of light emitted by light-emitting elements ED.

Each of the subpixels SPXn may further include a subarea SA, which is in the non-emission area of the corresponding subpixel SPXn. The subarea SA may be on a first side, in the first direction DR1, of the emission area EMA of the corresponding subpixel SPXn, between the emission area EMA of the corresponding subpixel SPXn and the emission area EMA of a neighboring subpixel SPXn adjacent to the corresponding subpixel SPXn in the first direction DR1. In one example, a plurality of emission areas EMA may be repeatedly arranged with each other in the second direction DR2, a plurality of subareas SA may be arranged repeatedly with each other in the second direction DR2, and the plurality of emission areas EMA and the plurality of subareas SA may be alternately arranged with each other in the first direction DR1. However, the present disclosure is not limited to this example.

A bank BNL may be between the subareas SA of the subpixels SPXn, between the emission areas EMA of the subpixels SPXn, and between the subareas SA and the emission areas EMA of the subpixels SPXn, the distances between the subareas SA of the subpixels SPXn, between the emission areas EMA of the subpixels SPXn, and between the subareas SA and the emission areas EMA of the subpixels SPXn may vary depending on the width of the bank BNL. As no light-emitting elements ED are provided in the subareas SA of the subpixels SPXn, no light may be output from the subareas SA of the subpixels SPXn, but electrodes RME may be positioned in parts in the subareas SA of the subpixels SPXn. Two groups of electrodes RME from two different subpixels SPXn may be separated from each other in a separation part ROP of a subarea SA of one of the two different subpixels SPXn. The electrodes RME may be connected (e.g., electrically and/or physically coupled) to first and second voltage lines through first electrode contact holes CTD and second electrode contact holes CTS.

The bank BNL may include parts that extend in the first direction DR1 and parts that extend in the second direction DR2, and may be arranged in a lattice pattern in a plan view over the entire display area DPA. The bank BNL may be positioned along the boundaries of each of the subpixels SPXn to separate the subpixels SPXn from one another. Also, the bank BNL may surround each of the emission areas EMA of the subpixels SPXn to separate the emission areas EMA of the subpixels SPXn from one another.

In the emission area EMA, connecting electrodes CNE, which overlap with the electrodes RME and are in contact with both sides of each of the light-emitting elements ED, may be provided. The connecting electrodes CNE may be connected (e.g., electrically and/or physically coupled) to the electrodes RME through conductive regions PCT of an organic layer OPL. The structures of the electrodes RME and the connecting electrodes CNE will be described herein below.

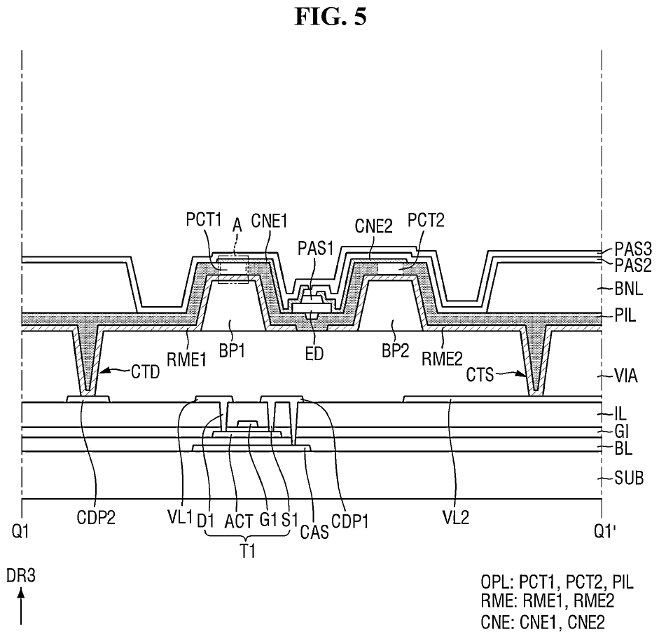

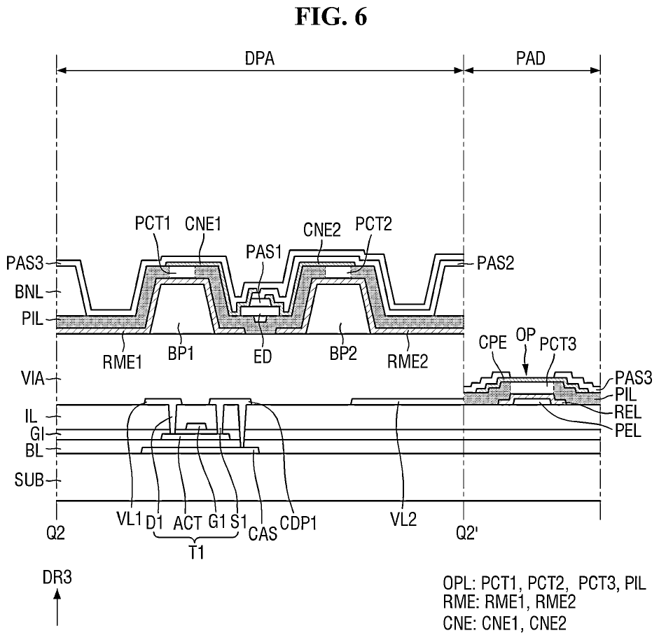

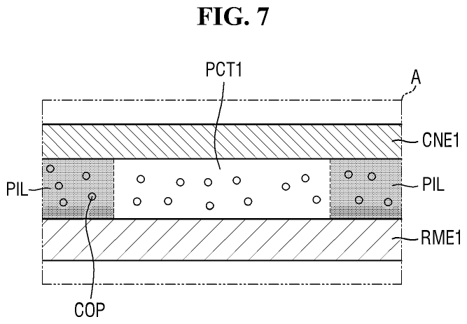

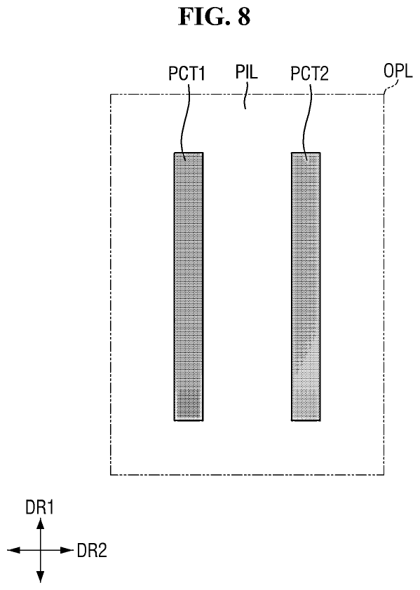

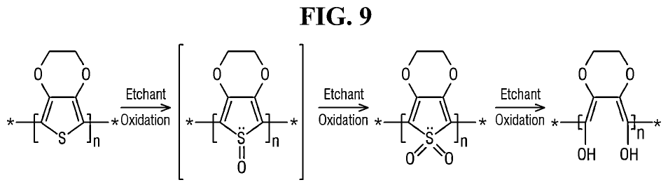

FIG. 5 is a cross-sectional view taken along line Q1-Q1′ of FIG. 4. FIG. 6 is a cross-sectional view taken along line Q2-Q2′ of FIG. 4 and illustrates portion of a pad area of the display device of FIG. 1. FIG. 7 is a cross-sectional view of part A of FIG. 5. FIG. 8 is a plan view of a portion of the organic layer of the display device of FIG. 1. FIG. 9 illustrates the chemical mechanism of the organic layer of the display device of FIG. 1.

Referring to FIGS. 5 and 6 and further to FIG. 4, the display device 10 may include a substrate SUB and may further include an active layer, a plurality of conductive layers, and a plurality of insulating layers, which are positioned on the substrate SUB. The active layer, the conductive layers, and the insulating layers may form a circuit layer and a display element layer of the display device 10.

The substrate SUB may be an insulating substrate. The substrate SUB may be formed of an insulating material such as glass, quartz, and/or a polymer resin. The substrate SUB may be a rigid substrate or may be a flexible substrate that is bendable, foldable, and/or rollable. The substrate SUB may include the display area DPA and the non-display area NDA, which surrounds the display area DPA, and may further include the pad area PDA, which accounts for portion of the non-display area NDA.

A first conductive layer may be provided on the substrate SUB. The first conductive layer includes a lower metal layer CAS, and the lower metal layer CAS may overlap with an active layer ACT of a first transistor T1. The lower metal layer CAS may include a material capable of blocking or reducing the transmission of light and may prevent or reduce the occurrence of a light being incident upon the active layer ACT of the first transistor T1. In one or more embodiments, the lower metal layer CAS may not be provided.

A buffer layer BL may be provided on the lower metal layer CAS and the substrate SUB. The buffer layer BL may be formed on the substrate SUB to protect the transistors of the pixel PX from moisture that may penetrate through the substrate SUB, which is vulnerable to moisture, and may perform a surface planarization function.

A semiconductor layer is provided on the buffer layer BL. The semiconductor layer may include the active layer ACT of the first transistor T1. The active layer ACT may partially overlap with a gate electrode G1 of a second conductive layer that will be described herein below.

The semiconductor layer may include polycrystalline silicon, monocrystalline silicon, and/or an oxide semiconductor. In one or more embodiments, the semiconductor layer may include polycrystalline silicon. The oxide semiconductor may be an oxide semiconductor containing indium (In). In one or more embodiments, the oxide semiconductor may be at least one of indium tin oxide (ITO), indium zinc oxide (IZO), indium gallium oxide (IGO), indium zin tin oxide (IZTO), indium gallium tin oxide (IGTO), or indium gallium zinc tin oxide (IGZTO).

FIGS. 5 through 8 illustrate that the first subpixel SPX1 includes only one transistor, i.e., the first transistor T1, but the present disclosure is not limited thereto. For example, the first subpixel SPX1 may include more than one transistor.

A gate insulating layer GI is provided on the semiconductor layer and the buffer layer BL. The gate insulating layer GI may function as a gate insulating film for the first transistor T1.

A second conductive layer is provided on the gate insulating layer GI. The second conductive layer may include a gate electrode G1 of the first transistor T1. The gate electrode G1 may overlap with the channel region of the active layer ACT in a thickness direction, i.e., in a third direction DR3.

An interlayer insulating layer IL is provided on the second conductive layer. The interlayer insulating layer IL may function as an insulating film between the second conductive layer and layers on the second conductive layer, and may protect the second conductive layer.

A third conductive layer is provided on the interlayer insulating layer IL. The third conductive layer may include first and second voltage lines VL1 and VL2, which are in the display area DPA, a plurality of conductive patterns (CDP1 and CDP2), and a pad electrode PEL, which is in the pad area PDA.

The high-potential voltage (or the first power supply voltage) to be delivered to a first electrode RME1 may be applied to the first voltage line VL1, and the low-potential voltage (or the second power supply voltage) to be delivered to a second electrode RME2 may be applied to the second voltage line VL2. Portion of the first voltage line VL1 may be in contact with the active layer ACT of the first transistor T1 through a contact hole that penetrates the interlayer insulating layer IL and the gate insulating layer GI. The first voltage line VL1 may function as a first drain electrode D1 of the first transistor T1. The second voltage line VL2 may be directly connected to a second electrode RME2 that will be described herein below.

A first electrode pattern CDP1 may be in contact with the active layer ACT of the first transistor T1 through a contact hole that penetrates the interlayer insulating layer IL and the gate insulating layer GI. Also, the first electrode pattern CDP1 may be in contact with the lower metal layer CAS through another contact hole. The first electrode pattern CDP1 may function as a first source electrode S1 of the first transistor T1.

A second conductive pattern CDP2 may be connected (e.g., physically coupled) to a first electrode RME1 that will be described herein below. Also, the second conductive pattern CDP2 may be electrically connected (e.g., electrically coupled) to the first transistor T1 via the first conductive pattern CDP1. The first and second conductive patterns CDP1 and CDP2 are illustrated as being separate from each other, but the present disclosure is not limited thereto. In one or more embodiments, the first and second conductive patterns CDP1 and CDP2 may be integrally formed to form a single pattern together. The first transistor T1 may transmit a first power supply voltage applied thereto from the first voltage line VL1 to the first electrode RME1.

Although the first and second conductive patterns CDP1 and CDP2 are illustrated as being formed in the same layer, but the present disclosure is not limited thereto. In one or more embodiments, the second conductive pattern CDP2 may be formed of (e.g., in) a different conductive layer from the first conductive pattern CDP1, for example, a fourth conductive layer, which is on the third conductive layer with one or more insulating layers interposed therebetween. In this case, the first and second voltage lines VL1 and VL2 may be formed of (e.g., in) the fourth conductive layer, instead of the third conductive layer, and the first voltage line VL1 may be electrically connected to the drain electrode D1 of the first transistor T1 via another conductive pattern.

The pad electrode PEL may be in the pad area PDA and may be connected (e.g., electrically and/or physically coupled) to one of the line pads WPD. The pad electrode PEL may be formed of (e.g., in) the third conductive layer. In one or more embodiments, the pad electrode PEL may be electrically connected to one of the lines in the display area DPA, and electrical signals from the line pads WPD may be transmitted to the lines in the display area DPA via the pad electrode PEL.

Each of the buffer layer BL, the gate insulating layer GI, and the interlayer insulating layer IL may include (e.g., may consist of) a plurality of inorganic layers that are alternately stacked. In one example, each of the buffer layer BL, the gate insulating layer GI, and the interlayer insulating layer IL may be formed as a double- or multilayer in which inorganic layers of at least one of silicon oxide (SiOₓ), silicon nitride (SiNₓ), or silicon oxynitride (SiOₓN_{y}) are alternately stacked, but the present disclosure is not limited thereto. In some embodiments, each of the buffer layer BL, the gate insulating layer GI, and the interlayer insulating layer IL may be formed as a single inorganic layer including silicon oxide (SiOₓ), silicon nitride (SiNₓ), and/or silicon oxynitride (SiOₓN_{y}). Also, in some embodiments, the interlayer insulating layer IL may be formed of an organic insulating material such as polyimide (PI).

The second and third conductive layers may be formed as single layers or multilayers including molybdenum (Mo), aluminum (Al), chromium (Cr), gold (Au), titanium (Ti), nickel (Ni), neodymium (Nd), copper (Cu), or an alloy thereof, but the present disclosure is not limited thereto.

A via layer VIA is provided on the third conductive layer, in the display area DPA. The via layer VIA may include an organic insulating material such as, for example, PI, and may perform a surface planarization function. As the via layer VIA is not in the pad area PDA, the pad electrode PEL, which is on the interlayer insulating layer IL, may not be covered by the via layer VIA.

Bank patterns (BP1 and BP2), a plurality of electrodes RME, a bank BNL, a plurality of light-emitting elements ED, and a plurality of connecting electrodes CNE are provided on the via layer VIA as the display element layer. A plurality of insulating layers (PAS1, PAS2, PAS3, and PAS4) may be positioned on the via layer VIA.

The bank patterns (BP1 and BP2) may be directly on the via layer VIA, in the display area DPA. The bank patterns (BP1 and BP2) may extend in the first direction DR1 and may be spaced apart from one another in the second direction DR2. In one example, the bank patterns (BP1 and BP2) may include first and second bank patterns BP1 and BP2, which are spaced apart from each other in the emission area EMA of the first subpixel SPX1. The first bank pattern BP1 may be on a first side, in the second direction DR2, of the center of the emission area EMA, e.g., on the left side of the center of the emission area EMA, and the second bank pattern BP2 may be on a second side, in the second direction DR2, of the center of the emission area EMA, e.g., on the right side of the center of the emission area EMA. The light-emitting elements ED may be between the first and second bank patterns BP1 and BP2.

The length, in the first direction DR1, of the bank patterns (BP1 and BP2) may be smaller than the length, in the first direction DR1, of the emission area EMA surrounded by the bank BNL. The bank patterns (BP1 and BP2) may be positioned in the emission area EMA of the first subpixel SPX1, over the entire surface of the display area DPA, to form island patterns that extend in one direction with a relatively small width. FIGS. 5 and 6 illustrate that two bank patterns (BP1 and BP2) having the same (or substantially the same) width are provided in each subpixel SPXn, but the present disclosure is not limited thereto. The number and shape of bank patterns (BP1 and BP2) may vary depending on the number and the pattern of arrangement of electrodes RME.

The bank patterns (BP1 and BP2) may protrude at least in part from the top surface of the via layer VIA. Protruding portions of the bank patterns (BP1 and BP2) may each have inclined side surfaces, and light emitted by the light-emitting elements ED may be reflected by portions of the electrodes RME on the bank patterns (BP1 and BP2), and may thus be emitted in an upward direction of the via layer VIA. However, the present disclosure is not limited to this. In one or more embodiments, each of the bank patterns (BP1 and BP2) may have a semicircular or semielliptical shape with a curved outer surface. The bank patterns (BP1 and BP2) may include an organic insulating material such as PI, but the present disclosure is not limited thereto.

The electrodes RME may be in the first subpixel SPX1 to extend in one direction. The electrodes RME may be in the emission area EMA of the first subpixel SPX1 to extend in the first direction DR1 and be spaced apart from one another in the second direction DR2. The electrodes RME may be electrically connected (e.g., electrically coupled) to the light-emitting elements ED. The electrodes RME may be connected to the light-emitting elements ED through the connecting electrodes CNE that will be described herein below, and may transmit electrical signals applied thereto from the underlying conductive layers to the light-emitting elements ED.

The display device 10 may include the first and second electrodes RME1 and RME2, which are in the first subpixel SPX1. The first electrode RME1 may be on the left side of the center of the emission area EMA of the first subpixel SPX1, and the second electrode RME2 may be on the right side of the center of the emission area EMA of the first subpixel SPX1. The first electrode RME1 may be on the first bank pattern BP1, and the second electrode RME2 may be on the second bank pattern BP2. The first and second electrodes RME1 and RME2 may be in part in the subarea SA of the first subpixel SPX1. The first and second electrodes RME1 and RME2 of the first subpixel SPX1 may be spaced apart from first and second electrodes RME1 and RME2 of another subpixel SPXn by a separation part ROP in the subarea SA of the first subpixel SPX1.

The first and second electrodes RME1 and RME2 may be positioned at least on inclined side surfaces of the bank patterns (BP1 and BP2). In one example, the width, in the second direction DR2, of the electrodes RME may be greater than the width, in the second direction DR2, of the bank patterns (BP1 and BP2). The first and second electrodes RME1 and RME2 may cover at least the side surfaces of the bank patterns (BP1 and BP2) and may thus reflect light emitted by the light-emitting elements ED.

The distance, in the second direction DR2, between the first and second electrodes RME1 and RME2 may be smaller than the distance, in the second direction DR2, between the bank patterns (BP1 and BP2). At least portions of the first and second electrodes RME1 and RME2 may be directly on the via layer VIA to be placed on the same plane. For example, at least portions of the first electrode RME1 and the second electrode RME2 may be in a same plane as a result of both being directly on the via layer VIA.

The electrodes RME may be on the bank patterns (BP1 and BP2), and light emitted by the light-emitting elements ED, which are positioned between the bank patterns (BP1 and BP2), may be emitted in an upward direction by being reflected by portions of the electrodes RME on the bank patterns (BP1 and BP2). The electrodes RME may include a conductive material with high reflectance and may thus reflect light emitted by the light-emitting elements ED.

The electrodes RME may include a material with high reflectance and high conductivity. In one example, the electrodes RME may include Al and/or an alloy of Al, Ni, lanthanum (La), and/or Cu. The electrodes RME may further include a material such as ITO, IZO, and/or indium tin zinc oxide (ITZO), or may have a structure in which one or more layers of ITO, IZO, and/or ITZO are stacked.

The electrodes RME may be electrically connected (e.g., electrically coupled) to the light-emitting elements ED via the connecting electrodes CNE that will be described herein below, and may be in direct contact with the connecting electrodes CNE and the third conductive layer. Elements including Al, such as the electrodes RME, may easily be damaged and/or may react with solutions during processes that follow the formation of the electrodes RME. If portions of the electrodes RME that are in contact with, for example, the connecting electrodes CNE react with a solution, the electrodes RME may not be properly connected electrically to electrodes from another layer, and/or the resistance of the electrodes RME may considerably increase at the interfaces with the connecting electrodes CNE. To prevent or reduce the risk of occurrence of any of these problems, a layer capable of protecting the electrodes RME such that the electrodes RME do not react with a solution may be provided. This will be described herein below in more detail.

The electrodes RME may extend from the emission area EMA to the subarea SA of the first subpixel SPX1 and may include parts overlapping with the bank BNL and parts positioned in the subarea SA. In one example, portions of the electrodes RME may be positioned in the subarea SA.

The first and second electrodes RME1 and RME2 may be connected (e.g., electrically and/or physically coupled) to the third conductive layer through first and second electrode contact holes CTD and CTS, respectively, which are formed in an area that overlaps with the bank BNL. The first electrode RME1 may be in contact with the second conductive pattern CDP2 through the first electrode contact hole CTD, which penetrates the via layer VIA. The second electrode RME2 may be in contact with the second voltage line VL2 through the second electrode contact hole CTS, which penetrates the via layer VIA. The first electrode RME1 may be electrically connected (e.g., electrically coupled) to the first transistor T1 via the first and second conductive patterns CDP1 and CDP2, and may thus receive the first power supply voltage, and the second electrode RME2 may be electrically connected (e.g., electrically coupled) to the second voltage line VL2 and may thus receive the second power supply voltage.

In one or more embodiments, the pad electrode PEL, which is formed of the third conductive layer, is provided in the pad area PDA, and a pad electrode upper layer REL may be on the pad electrode PEL. The pad electrode upper layer REL may be formed of the same material as the electrodes RME. The pad electrode upper layer REL may be larger than the pad electrode PEL and may thus cover the pad electrode PEL.

The organic layer OPL may be in the display area DPA and the pad area PDA, on the electrodes RME and the pad electrode upper layer REL. The organic layer OPL may protect the electrodes RME and the pad electrode upper layer REL and may insulate the electrodes RME from each other. As the organic layer OPL covers the electrodes RME before the formation of the bank BNL, the organic layer OPL can prevent or reduce damage to the electrodes RME during the formation of the bank BNL. Also, the organic layer OPL can prevent or reduce damage to the light-emitting elements ED, which are on the organic layer OPL, and/or direct contact of the light-emitting elements ED with other elements.

In one or more embodiments, the organic layer OPL may be formed to be recessed in part between the electrodes RME, which are spaced apart from each other in the second direction DR2. The light-emitting elements ED may be on the top surface of a recessed portion of the organic layer OPL, and a gap or space may be formed between the organic layer OPL and the light-emitting elements ED. The organic layer OPL may cover the electrodes RME and the pad electrode upper layer REL.

Referring to FIGS. 7 through 9 and further to FIGS. 5 and 6, the organic layer OPL may include conductive regions PCT and an insulating region PIL, which is a region other than the conductive regions PCT. The organic layer OPL may include poly(3,4-ethylenedioxythiophene):poly(styrenesulfonic acid) (PEDOT:PSS). As the PEDOT:PSS reacts with an etchant, the thiophene of the PEDOT of the PEDOT:PSS is desulfurized and oxidized, and oxygen double bonds are formed so that the conductivity of the PEDOT:PSS may considerably decrease and the PEDOT:PSS may exhibit dielectricity (e.g., dielectric characteristics). For example, in embodiments where the organic layer OPL is formed of PEDOT:PSS, portion of the organic layer OPL that is exposed to the etchant may be formed as the insulating region PIL, and portion of the organic layer OPL that is not exposed to the etchant may be formed as the conductive regions PCT having the original conductivity of the organic layer OPL. Here, a sodium- or potassium-based compound such as, for example, sodium hypochlorite (NaOCl), may be used as the etchant.

The conductive regions PCT of the organic layer OPL may include a compound expressed by Formula 1 below, and the insulating region PIL of the organic layer OPL may include a compound expressed by Formula 2 below.

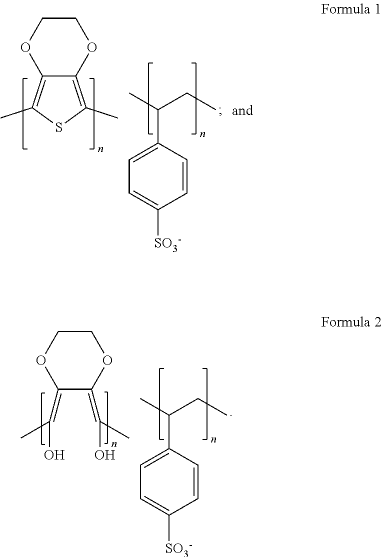

In Formulae 1 and 2, n is an integer equal to or greater than 1.

The conductive regions PCT may include a first conductive region PCT1, which overlaps with the first electrode RME1 and a first connecting electrode CNE1, a second conductive region PCT2, which overlaps with the second electrode RME2 and a second connecting electrode CNE2, and a third conductive region PCT3, which overlaps with the pad electrode upper layer REL and a pad electrode capping layer CPE. The first and second conductive regions PCT1 and PCT2 may be in the emission area EMA, and the third conductive region PCT3 may be in the pad area PDA.

A first surface of the first conductive region PCT1 may be in contact (e.g., in physical contact) with the first electrode RME1, on the first bank pattern BP1, and a second surface of the first conductive region PCT1 that is opposite to the first surface of the first conductive region PCT1 may be in contact (e.g., in physical contact) with the first connecting electrode CNE1. The first conductive region PCT1 may overlap with the first bank pattern BP1, the first electrode RME1, and the first connecting electrode CNE1. The first conductive region PCT1 may electrically connect (e.g., electrically couple) the first electrode RME1 and the first connecting electrode CNE1. A first surface of the second conductive region PCT2 may be in contact (e.g., in physical contact) with the second electrode RME2, on the second bank pattern BP2, and a second surface of the second conductive region PCT2 that is opposite to the first surface of the second conductive region PCT2 may be in contact (e.g., in physical contact) with the second connecting electrode CNE2. The second conductive region PCT2 may overlap with the second bank pattern BP2, the second electrode RME2, and the second connecting electrode CNE2. The second conductive region PCT2 may electrically connect (e.g., electrically couple) the second electrode RME2 and the second connecting electrode CNE2. The first and second conductive regions PCT1 and PCT2 may extend in the first direction DR1, in the emission area EMA, and may be spaced apart from each other in the second direction DR2.

A first surface of the third conductive region PCT3 may be in contact (e.g., in physical contact) with the pad electrode upper layer REL, on the pad electrode PEL, and a second surface of the third conductive region PCT3 that is opposite to the first surface of the third conductive region PCT3 may be in contact (e.g., in physical contact) with the pad electrode capping layer CPE. The third conductive region PCT3 may electrically connect (e.g., electrically couple) the pad electrode PEL, the pad electrode upper layer REL, and the pad electrode capping layer CPE.

The insulating region PIL may account for the entire organic layer OPL except for the conductive regions PCT. In one or more embodiments, the insulating region PIL may account for regions that overlap with the bank BNL and the entire emission area EMA, except for the first and second conductive regions PCT1 and PCT2.

In one or more embodiments, the surface roughness of the insulating region PIL of the organic layer OPL may be greater than the surface roughness of the conductive regions PCT of the organic layer OPL. As the surfaces of the insulating region PIL are exposed to an etchant so that at least a portion of the surface of the insulating region PIL is etched by the etchant, the surface roughness of the insulating region PIL may be greater than the surface roughness of the conductive regions PCT that are not etched. However, the difference between the surface roughness of the insulating region PIL and the surface roughness of the conductive regions PCT may be almost ignorable (e.g., negligible).

The organic layer OPL may further include conductive particles COP. The conductive particles COP may be added to improve the conductivity of the conductive regions PCT. Only a small amount of conductive particles COP may be added for the insulating region PIL to maintain their dielectricity (e.g., their dielectric characteristics). In one example, 1 wt % to 10 wt % of conductive particles COP may be included with respect to 100 wt % of the organic layer OPL. The conductive particles COP may be silver (Ag) nanowires, a metal, and/or graphene, but the present disclosure is not limited thereto. For example, various other suitable conductive particles may also be used.

As described above, electrodes RME including Al may react with a developing agent such as tetramethylammonium hydroxide (TMAH) during processes that follow the formation of the electrodes RME. When the electrodes RME are exposed to a developing agent, a galvanic phenomenon occurs due to the difference in standard reduction potential between the electrodes RME and the connecting electrodes CNE. As a result, a problem may arise in connection with the electrical connection between the electrodes RME and the connecting electrodes CNE, and/or the resistances on the surfaces of contact between the electrodes RME and the connecting electrodes CNE may considerably increase.

In the display device 10, the organic layer OPL, which covers the electrodes RME, may be formed, and the conductive regions PCT may be formed in the organic layer OPL without exposing the electrodes RME. The conductive regions PCT of the organic layer OPL may electrically connect (e.g., electrically couple) the connecting electrodes CNE to the electrodes RME. Accordingly, as the exposure of the electrodes RME to a developing agent and/or the like due to the presence of the organic layer OPL may be prevented or reduced, the occurrence of a galvanic phenomenon in the electrodes RME can be prevented or reduced, and an increase in the resistance between the electrodes RME and the connecting electrodes CNE can be prevented or reduced.

The third conductive region PCT3 of the organic layer OPL may be formed on the pad electrode upper layer REL, which is formed of the same material as the electrodes RME, in the pad area PDA, and the pad electrode capping layer CPE may be provided on the organic layer OPL. The third conductive region PCT3 may electrically connect (e.g., electrically couple) the pad electrode upper layer REL and the pad electrode capping layer CPE without exposing the pad electrode upper layer REL, and may thus prevent or reduce the exposure of the pad electrode upper layer REL to a developing agent and/or the like.

In one or more embodiments, the bank BNL may be provided on the organic layer OPL. The bank BNL may include parts extending in the first direction DR1 and parts extending in the second direction DR2, and may surround each subpixel SPXn. Also, the bank BNL may surround the emission area EMA and the subarea SA of each subpixel SPXn to separate the emission area EMA and the subarea SA of each subpixel SPXn, and may surround the outermost portions of the display area DPA to separate the display area DPA and the non-display area NDA. The bank BNL may be in the entire display area DPA to form a lattice pattern, and portions of the display area DPA opened by the bank BNL may be the emission area EMA and the subarea SA of each subpixel SPXn.

The bank BNL, like the bank patterns (BP1 and BP2), may have a set or predetermined height. In some embodiments, the height of the top surface of the bank BNL may be greater than the height of the bank patterns (BP1 and BP2), and the thickness of the bank BNL may be the same as or greater than the thickness of the bank patterns (BP1 and BP2). The bank BNL may prevent or reduce the spilling over of ink between neighboring subpixels SPXn during inkjet printing during the fabrication of the display device 10. The bank BNL, like the bank patterns (BP1 and BP2), may include an organic insulating material such as PI.

The light-emitting elements ED may be provided on the organic layer OPL. The light-emitting elements ED may extend in one direction and may be arranged such that the direction in which the light-emitting elements ED extend may be parallel to the substrate SUB. Each of the light-emitting elements ED may include a plurality of semiconductor layers, which are sequentially arranged in a direction parallel to the top surface of the substrate SUB, but the present disclosure is not limited thereto. In one or more embodiments, the semiconductor layers may be arranged in a direction perpendicular (or substantially perpendicular) to the substrate SUB.

The light-emitting elements SED may be provided on the electrodes RME that are spaced apart from each other in the second direction DR2 between the bank patterns (BP1 and BP2). The length of the light-emitting elements ED may be greater than the distance, in the second direction DR2, between the electrodes RME. At least one end portion of each of the light-emitting elements ED may be positioned on one of the electrodes RME, and both end portions of each of the light-emitting elements ED may be on different electrodes RME. The light-emitting elements ED may be arranged such that the direction in which the light-emitting elements ED extend may be substantially perpendicular to the direction in which the electrodes RME extend. The light-emitting elements ED may be spaced apart from one another in the direction in which the light-emitting elements RME extend, i.e., in the first direction DR1, and may be aligned substantially in parallel to one another, but the present disclosure is not limited thereto. In one or more embodiments, the light-emitting elements ED may be arranged diagonally (or substantially diagonally) with respect to the direction in which the electrodes RME extend.

The wavelength range of light emitted by the light-emitting elements ED may differ from one subpixel SPXn to another subpixel SPXn depending on the materials of the semiconductor layers included in each of the light-emitting elements ED, but the present disclosure is not limited thereto. In one or more embodiments, the semiconductor layers included in each of the light-emitting elements ED may include the same materials throughout different subpixels SPXn and may thus emit light of the same color throughout different subpixels SPXn. As the light-emitting elements ED are in contact with the connecting electrodes CNE, the light-emitting elements ED may be electrically connected (e.g., electrically coupled) to the electrodes RME and the conductive layers below the via layer VIA and may emit light of a particular wavelength range in response to electrical signals being applied thereto.

A first insulating layer PAS1 may be provided on the light-emitting elements ED, the organic layer OPL, and the bank BNL. The first insulating layer PAS1 may include pattern parts, which extend in the first direction DR1 between the bank patterns (BP1 and BP2), and may be provided on the light-emitting elements ED. The pattern parts may surround portions of the outer surfaces of each of the light-emitting elements ED, but not cover both sides or both end portions of each of the light-emitting elements ED. The pattern parts may form linear or island patterns in the first subpixel SPX1 in a plan view. The pattern portions of the first insulating layer PAS1 may protect and fix the light-emitting elements ED during the fabrication of the display device 10. Also, the first insulating layer PAS1 may fill the gap between the light-emitting elements ED and the organic layer OPL. Also, portions of the first insulating layer PAS1 may be on the bank BNL and in the subarea SA. The first insulating layer PAS1 may be in the subarea SA, but not in the separation part ROP.

The first insulating layer PAS1 may not be in the pad area PDA. As only the organic layer OPL and a third insulating layer PAS3 that will be described herein below are provided in the pad area PDA, the height difference between the pad electrode upper layer REL and the pad electrode capping layer CPE can be minimized or reduced.

The connecting electrodes CNE may be on, and in contact with (e.g., physical contact), the electrodes RME and the light-emitting elements ED. The connecting electrodes CNE may be in contact with end portions of the light-emitting elements ED and with at least one of the electrodes RME through the conductive regions PCT of the organic layer OPL.

A first connecting electrode CNE1 may extend in the first direction DR1 and may be on the first electrode RME1. Portion of the first connecting electrode CNE1 on the first bank pattern BP1 may overlap with the first electrode RME1 and may extend from the first electrode RME1 in the first direction DR1. The first connecting electrode CNE1 may be in the emission area EMA, but not in the subarea SA. As the first connecting electrode CNE1 is in direct contact with the first conductive region PCT1 of the organic layer OPL to be connected (e.g., electrically and/or physically coupled) to the first electrode RME1 and the first end portions of the light-emitting elements ED, the first connecting electrode CNE1 may transmit electrical signals from the first transistor T1 to the light-emitting elements ED.

A second connecting electrode CNE2 may extend in the first direction DR1 and may be on the second electrode RME2. Portion of the second connecting electrode CNE2 on the second bank pattern BP2 may overlap with the second electrode RME2 and may extend from the second electrode RME2 in the first direction DR1. The second connecting electrode CNE2 may be in the emission area EMA, but not in the subarea SA. As the second connecting electrode CNE2 is in direct contact with the second conductive region PCT2 of the organic layer OPL to be connected (e.g., electrically and/or physically coupled) to the second electrode RME2 and the second end portions of the light-emitting elements ED, the second connecting electrode CNE2 may transmit electrical signals from the second voltage line VL2 to the light-emitting elements ED.

The second insulating layer PAS2 may be provided on the second connecting electrode CNE2 and the first insulating layer PAS1. The second insulating layer PAS2 may be on the entire surface of the first insulating layer PAS1 to cover the second connecting electrode CNE2, and the first connecting electrode CNE1 may be on the second insulating layer PAS2. The second insulating layer PAS2 may be on the entire surface of the via layer VIA, except for an area where the second connecting electrode CNE2 is positioned. The second insulating layer PAS2 may insulate the first and second connecting electrodes CNE1 and CNE2 from each other so that the first and second connecting electrodes CNE1 and CNE2 may not be in direct contact with each other.

The pad electrode capping layer CPE may be on the organic layer OPL in the pad area PDA and may be in direct contact with the pad electrode upper layer REL. The pad electrode capping layer CPE may include the same material as the connecting electrodes CNE, and the pad electrode capping layer CPE and the connecting electrodes CNE may be formed by the same process. The pad electrode capping layer CPE may be formed during the formation of the first and/or second connecting electrode CNE1 and/or CNE2. The pad electrode capping layer CPE, like the connecting electrodes CNE, may include a conductive material. The pad electrode capping layer CPE may be in contact (e.g., physical contact) with the third conductive region PC3 of the organic layer OPL and may be electrically connected (e.g., electrically coupled) to the pad electrode upper layer REL and the pad electrode PEL via the third conductive region PCT3. Also, the pad electrode capping layer CPE may prevent damage to the pad electrode PEL.

A third insulating layer PAS3 may be on the first connecting electrode CNE1 and the second insulating layer PAS2. The third insulating layer PAS3 may be on the entire surface of the substrate SUB and may protect the layers therebelow. The third insulating layer PAS3 may be positioned in part in the pad area PDA and may cover at least a portion of the pad electrode capping layer CPE in the pad area PDA. The third insulating layer PAS3 may include a pad hole OP, which exposes at least a portion of the pad electrode capping layer CPE.

The first, second, and third insulating layers PAS1, PAS2, and PAS3 may each independently include an inorganic insulating material or an organic insulating material.

The organic layer OPL, which covers the electrode RME including Al, may be formed, and the conductive regions PCT may be formed in the organic layer OPL without exposing the electrodes RME. The conductive regions PCT of the organic layer OPL may electrically connect (e.g., electrically couple) the connecting electrodes CNE and the electrodes RME. As a result, as the exposure of the electrodes RME to a developing agent and/or the like due to the presence of the organic layer OPL can be prevented or reduced, the occurrence of a galvanic phenomenon in the electrodes RME can be prevented or reduced, and an increase in the resistance between the electrodes RME and the connecting electrodes CNE can be prevented or reduced.

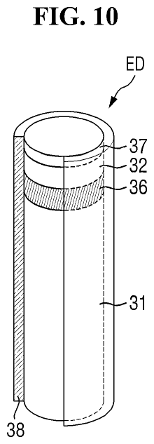

FIG. 10 is a perspective view of a light-emitting element according to one or more embodiments of the present disclosure.

Referring to FIG. 10, a light-emitting element ED may be an LED, for example, an ILED having a size of several nanometers or micrometers and formed of an inorganic material. If an electric field is formed in a particular direction between two opposite electrodes, the light-emitting element ED may be aligned between the two electrodes where polarities are formed.

The light-emitting element ED may have a shape that extends in one direction. The light-emitting element ED may have the shape of a cylinder, a rod, a wire, and/or a tube, but the shape of the light-emitting element ED is not particularly limited. In one or more embodiments, the light-emitting element ED may have the shape of a polygonal column such as a regular cube, a rectangular parallelepiped, or a hexagonal column, and/or may have a shape that extends in one direction but with a partially inclined outer surface.

The light-emitting element ED may include semiconductor layers doped with impurities of an arbitrary (e.g., particular) conductivity type (e.g., a p type or an n type). The semiconductor layers may receive electrical signals from an external power source to emit light of a particular wavelength range. The light-emitting element ED may include a first semiconductor layer 31, a second semiconductor layer 32, a light-emitting layer 36, an electrode layer 37, and the insulating film 38.

The first semiconductor layer 31 may include an n-type semiconductor. The first semiconductor layer 31 may include a semiconductor material, e.g., AlₓGa_{y}In_{1-x-y}N (where 0≤x≤1, 0≤y≤1, and 0≤x+y≤1). In one or more embodiments, the first semiconductor layer 31 may include at least one of AlGaInN, GaN, AlGaN, InGaN, AlN, or InN that are doped with an n-type dopant. The n-type dopant may be Si, Ge, and/or Sn.

The second semiconductor layer 32 may be on the first semiconductor layer 31 with the light-emitting layer 36 interposed therebetween. The second semiconductor layer 32 may include a p-type semiconductor. The second semiconductor layer 32 may include a semiconductor material, e.g., AlₓGa_{y}In_{1-x-y}N (where 0≤x≤1, 0≤y≤1, and 0≤x+y≤1). In one or more embodiments, the second semiconductor layer 32 may include at least one of AlGaInN, GaN, AlGaN, InGaN, AlN, or InN that are doped with a p-type dopant. The p-type dopant may be Mg, Zn, Ca, Se, and/or Ba.

FIG. 10 illustrates that the first and second semiconductor layers 31 and 32 are formed as single layers, but the present disclosure is not limited thereto. In one or more embodiments, each of the first and second semiconductor layers 31 and 32 may include more than one layer such as, for example, a clad layer and/or a tensile strain barrier reducing (TSBR) layer, depending on the material of the light-emitting layer 36.

The light-emitting layer 36 may be between the first and second semiconductor layers 31 and 32. The light-emitting layer 36 may include a single- or multi-quantum well structure material. In embodiments where the light-emitting layer 36 includes a material having a multi-quantum well structure, the light-emitting layer 36 may have a structure in which multiple quantum layers and multiple well layers are alternately stacked. The light-emitting layer 36 may emit light by combining electron-hole pairs in accordance with electrical signals applied thereto via the first and second semiconductor layers 31 and 32. The light-emitting layer 36 may include a material such as AlGaN and/or AlGaInN. In embodiments where the light-emitting layer 36 has a multi-quantum well structure in which multiple quantum layers and multiple well layers are alternately stacked, the quantum layers may include a material such as AlGaN and/or AlGaInN, and the well layers may include a material such as GaN and/or AlInN.

The light-emitting layer 36 may have a structure in which a semiconductor material having a large band gap energy and a semiconductor material having a small band gap energy are alternately stacked, or may include group-III or group-V semiconductor materials, depending on the wavelength of light to be emitted. The type (or kind) of light emitted by the light-emitting layer 36 is not particularly limited. For example, the light-emitting layer 36 may emit light of a red or green wavelength range as necessary, instead of blue light.

The electrode layer 37 may be an ohmic connecting electrode, but the present disclosure is not limited thereto. In one or more embodiments, the electrode layer 37 may be a Schottky connecting electrode. The light-emitting element ED may include at least one electrode layer 37. The light-emitting element ED may include more than one electrode layer 37, but the present disclosure is not limited thereto. In one or more embodiments, the electrode layer 37 may not be provided.

The electrode layer 37 may reduce the resistance between the light-emitting element ED and electrodes RME when the light-emitting element ED is electrically connected (e.g., electrically coupled) to the electrodes RME. The electrode layer 37 may include a conductive metal. In one or more embodiments, the electrode layer 37 may include at least one of Al, Ti, In, Au, Ag, ITO, IZO, or ITZO.

The insulating film 38 may surround the first and second semiconductor layers 31 and 32 and the electrode layer 37. In one or more embodiments, the insulating film 38 may surround at least the light-emitting layer 36, but may expose both end portions, in the length direction, of the light-emitting element ED. The insulating film 38 may be formed to be rounded in a cross-sectional view, in a region adjacent to at least one end of the light-emitting element ED.

The insulating film 38 may include a material with insulating properties such as, for example, silicon oxide (SiOₓ), silicon nitride (SiNₓ), silicon oxynitride (SiOₓN_{y}), aluminum nitride (AlNₓ), and/or aluminum oxide (AlOₓ). The insulating film 38 is illustrated as being a single-layer film, but the present disclosure is not limited thereto. In some embodiments, the insulating film 38 may be formed as a multilayer film in which multiple layers are stacked.

The insulating film 38 may protect the other elements of the light-emitting element ED. The insulating film 38 can prevent or reduce the risk of a short circuit that may occur in the light-emitting element layer 36 if the light-emitting element ED is in direct contact with electrodes to which electrical signals are applied. Also, the insulating film 38 can prevent or reduce the degradation of the emission efficiency of the light-emitting element ED.

The outer surface of the insulating film 38 may be subjected to surface treatment. The light-emitting element ED may be sprayed on electrodes while being dispersed in a set or predetermined ink. Here, the surface of the insulating film 38 may be hydrophobically or hydrophilically treated to keep the light-emitting element ED dispersed in ink without agglomerating with other neighboring light-emitting elements ED.

The fabrication of the display device 10 will hereinafter be described.

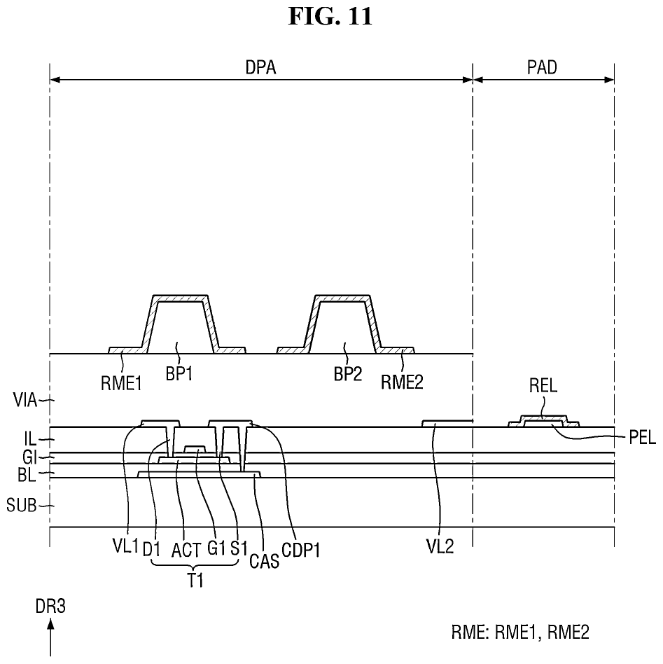

FIGS. 11 through 19 are cross-sectional views illustrating how to fabricate a display device according to one or more embodiments of the present disclosure. FIGS. 11 through 19 are cross-sectional views illustrating the structure of one subpixel SPXn of the display device 10 in accordance with the order in which layers are formed in the corresponding subpixel SPXn. FIGS. 11 through 19 illustrate mainly the order in which the organic layer OPL is formed in the display area DPA and the pad area PDA, and the cross-sectional views of FIGS. 11 through 19 correspond to the cross-sectional view of FIG. 6. Layers of the organic layer OPL may be formed by any suitable patterning process, and detailed descriptions of how to form layers of the organic layer OPL through a suitable patterning process will be omitted or simplified.

Referring to FIG. 11, the substrate SUB is prepared, and the first, second, and third conductive layers, the buffer layer BL, the gate insulating layer GI, the interlayer insulating layer IL, and the via layer VIA are formed on the substrate SUB. Each of the first, second, and third conductive layers may be formed by depositing a set or predetermined material such as, for example, a metallic material, and patterning the set or predetermined material through photolithography. Each of the buffer layer BL, the gate insulating layer GI, the interlayer insulating layer IL, and the via layer VIA may be formed by depositing a set or predetermined material such as, for example, an insulating material, and patterning the set or predetermined material with the use of a mask (as needed).

Thereafter, the bank patterns (BP1 and BP2) are formed on the via layer VIA, in the display area DPA, and a metallic material is deposited on the entire surface of the substrate SUB. Thereafter, in the display area DPA, the first and second electrodes RME1 and RME2 are formed on the first and second bank patterns BP1 and BP2, respectively, and in the pad area PDA, the pad electrode upper layer REL is formed on the pad electrode PEL.

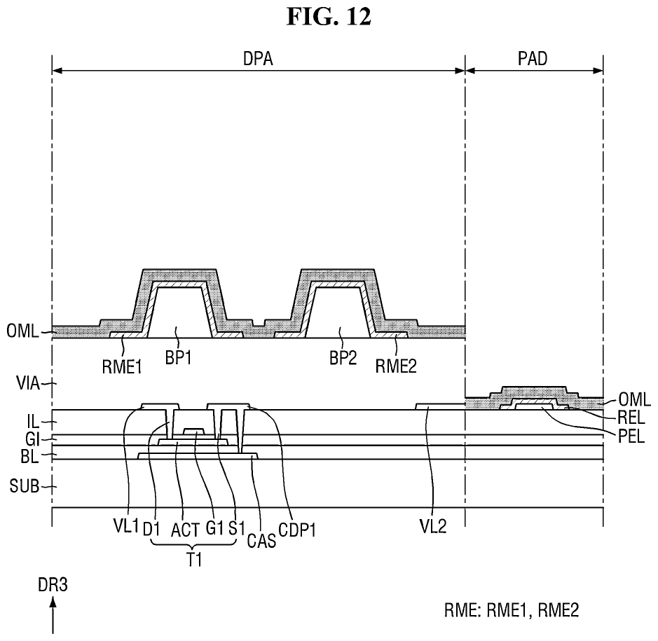

Thereafter, referring to FIG. 12, an organic material layer OML is applied on the entire surface of the substrate SUB. The organic material layer OML may be directly on the via layer VIA and the first and second electrodes RME1 and RME2, in the display area DPA, and on the pad electrode upper layer REL and the interlayer insulating layer IL, in the pad area PDA. In one example, the organic material layer OML may include PEDOT:PSS. The organic material layer OML is illustrated as not being flat and may be unevenly applied depending on the thickness of the organic material layer OML, but the present disclosure is not limited thereto. In one or more embodiments, the organic material layer OML may be evenly (or substantially evenly) applied.

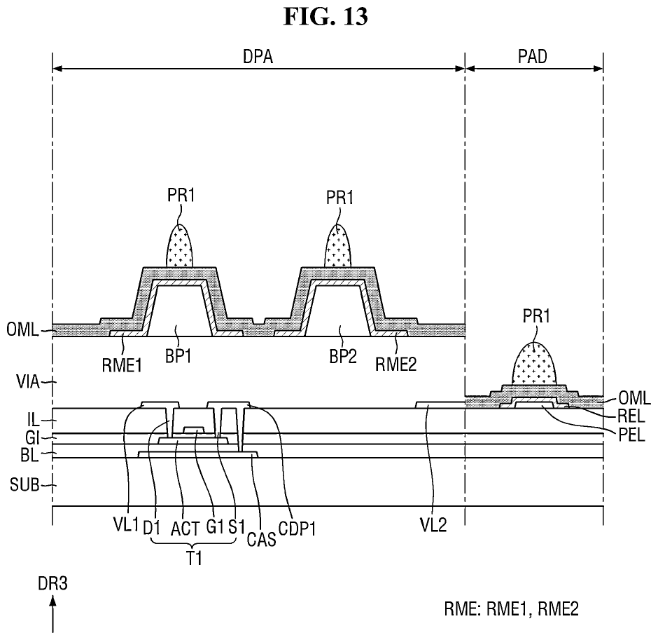

Thereafter, referring to FIG. 13, a photoresist pattern PR1 is formed on the organic material layer OML. The photoresist pattern PR1 may be formed by applying a photoresist layer on the entire surface of the organic material layer OML and subjecting the photoresist layer to exposure and development. The photoresist pattern PR1 may be used as a mask for forming the conductive regions PCT and the insulating region PIL of the organic layer OPL. The photoresist pattern PR1 may be in a region that overlaps with the first electrode RME1, on the first bank pattern BP1, in a region that overlaps with the second electrode RME2, on the second bank pattern BP2, and in a region that overlaps with the pad electrode upper layer REL, in the pad area PDA.

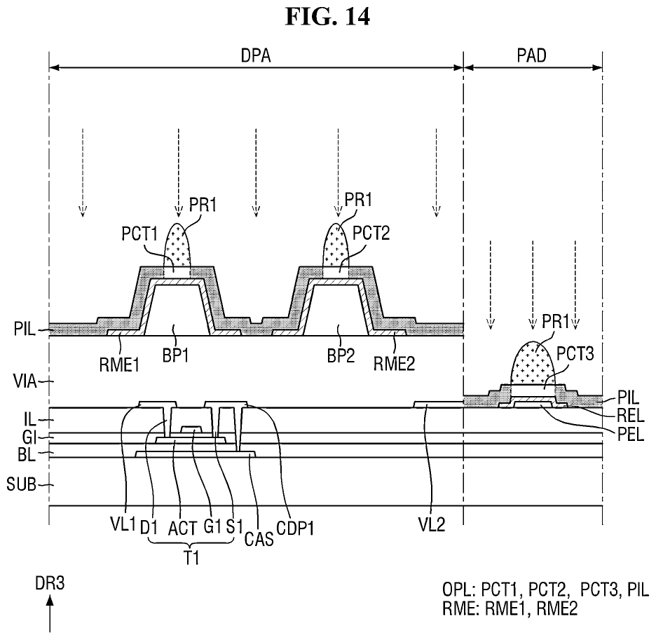

Thereafter, referring to FIG. 14, an etching process is performed on the organic material layer OML using the photoresist pattern PR1 as a mask. In one or more embodiments, an etchant is sprayed onto the substrate SUB where the photoresist pattern PR1 is formed. The etchant may cause a chemical reaction with the organic material layer OML upon contact with portions of the organic material layer OML exposed by the photoresist pattern PR1. As already mentioned above, the PEDOT moieties of the PEDOT:PSS of the organic material layer OML are desulfurized and oxidized by the etchant. As a result, portion of the organic material layer OML that reacts with the etchant may be formed as the insulating region PIL, and portion of the organic material layer OML that does not react with the etchant due to the presence of the photoresist pattern PR1 may be formed as the conductive regions PCT having the original conductivity of the organic material layer OML.

In one or more embodiments, portion of the organic material layer OML that does not react with the etchant due to the photoresist pattern PR1 and overlaps with the first electrode RME1 may be formed as the first conductive region PCT1, and portion of the organic material layer OML that does not react with the etchant due to the photoresist pattern PR1 and overlaps with the second electrode RME2 may be formed as the second conductive region PCT2. Portion of the organic material layer OML in the pad area PDA that does not react with the etchant due to the photoresist pattern PR1 may be formed as the third conductive region PCT3. The portion of the organic material layer OML that reacts with the etchant may be formed as the insulating region PIL. Here, the etchant may be a sodium- or potassium-based etchant such as, for example, sodium hypochlorite.

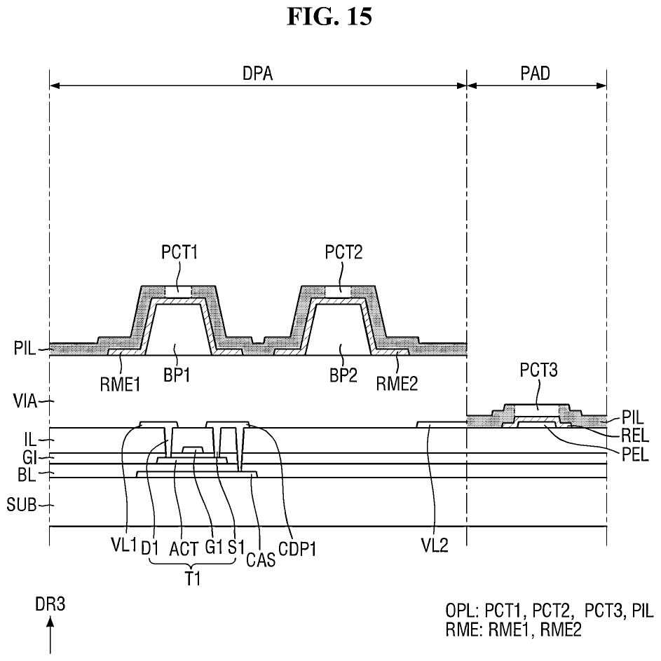

Thereafter, referring to FIG. 15, the photoresist pattern PR1 is removed, and as a result, the organic layer OPL, which includes the first, second, and third conductive regions PCT1, PCT2, and PCT3 and the insulating region PIL, is formed.

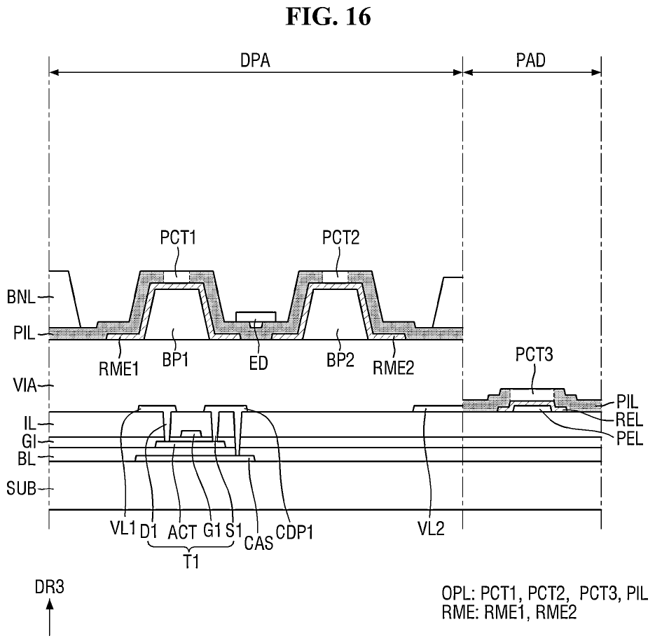

Thereafter, referring to FIG. 16, the bank BNL, which is on the organic layer OPL, is formed, and the light-emitting elements ED are provided on the first and second electrodes RME1 and RME2.

In one or more embodiments, the light-emitting elements ED may be on the electrodes RME through inkjet printing. As ink having the light-emitting elements ED dispersed therein is sprayed into the area surrounded by the bank BNL and electrical signals are applied to the electrodes RME, the locations and the alignment directions of the light-emitting elements ED in the ink are changing so that the light-emitting elements ED can be mounted on the electrodes RME.

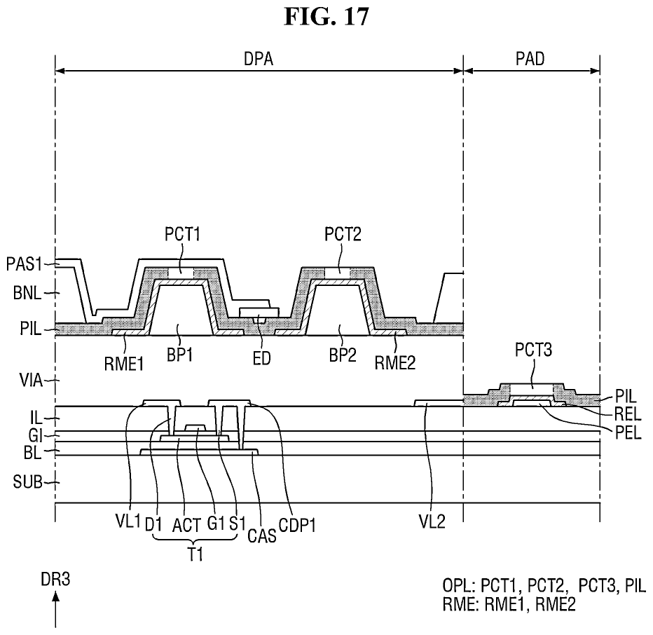

Thereafter, referring to FIG. 17, the first insulating layer PAS1 is formed on the light-emitting elements ED and the organic layer OPL in the display area DPA. The first insulating layer PAS1 may not be in the pad area PDA. The first insulating layer PAS1 may cover and fix (e.g., affix) the light-emitting elements ED. The first insulating layer PAS1 may initially be applied on the entire surface of the organic layer OPL in the display area DPA and may then be patterned to expose both end portions of each of the light-emitting elements ED. FIG. 17 illustrates that the first insulating layer PAS1 may expose the first end portions of the light-emitting elements ED. The first insulating layer PAS1 may be patterned later to expose the second end portions of the light-emitting elements ED.

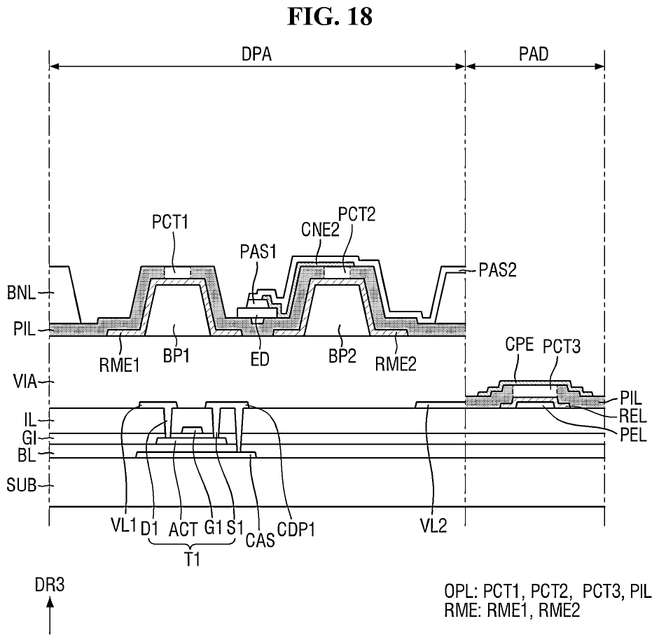

Thereafter, referring to FIG. 18, the second connecting electrode CNE2, which is in the display area DPA, and the pad electrode capping layer CPE, which is in the pad area PDA, are formed, and the second insulating layer PAS2 is formed on the pad electrode capping layer CPE. The second connecting electrode CNE2 may be in contact with the first end portions of the light-emitting elements ED exposed by the first insulating layer PAS1 and with the second conductive region PCT2 of the organic layer OPL, and the pad electrode capping layer CPE may be in contact with the third conductive region PCT3 of the organic layer OPL. The second insulating layer PAS2 may be on the first insulating layer PAS1, the second connecting electrode CNE2, and the organic layer OPL, and may be formed to expose the second end portions of the light-emitting elements ED, together with the first insulating layer PAS1. The second insulating layer PAS2 may not be on the pad electrode capping layer CPE in the pad area PDA.

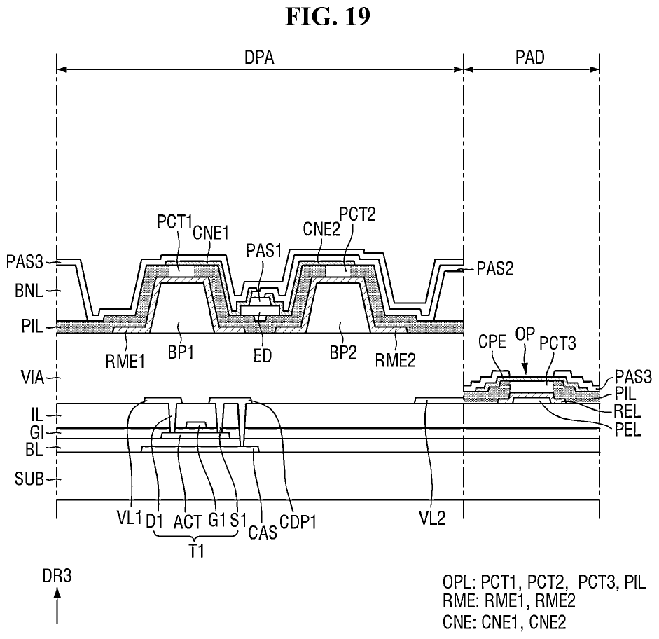

Thereafter, referring to FIG. 19, the first connecting electrode CNE1, which is in the display area DPA, is formed, and the third insulating layer PAS3 is formed on the first connecting electrode CNE1. The first connecting electrode CNE1 may be in contact with the second end portions of the light-emitting elements ED exposed by the second insulating layer PAS2 and with the first conductive region PCT1 of the organic layer OPL. The third insulating layer PAS3 may cover the first connecting electrode CNE1 and the second insulating layer PAS2, and may cover portion of the pad electrode capping layer CPE in the pad area PDA. In this manner, the display device 10 can be obtained.

According to the embodiments of FIGS. 11 through 19, even if a developing agent is applied during the formation of the first and second connecting electrodes CNE1 and CNE2, the occurrence of galvanic corrosion between the electrodes RME and the connecting electrodes CNE that may be caused by the developing agent can be prevented or reduced because the organic layer OPL covers and protects the electrodes RME and the pad electrode upper layer REL.

Display devices according to one or more other embodiments of the present disclosure will hereinafter be described.

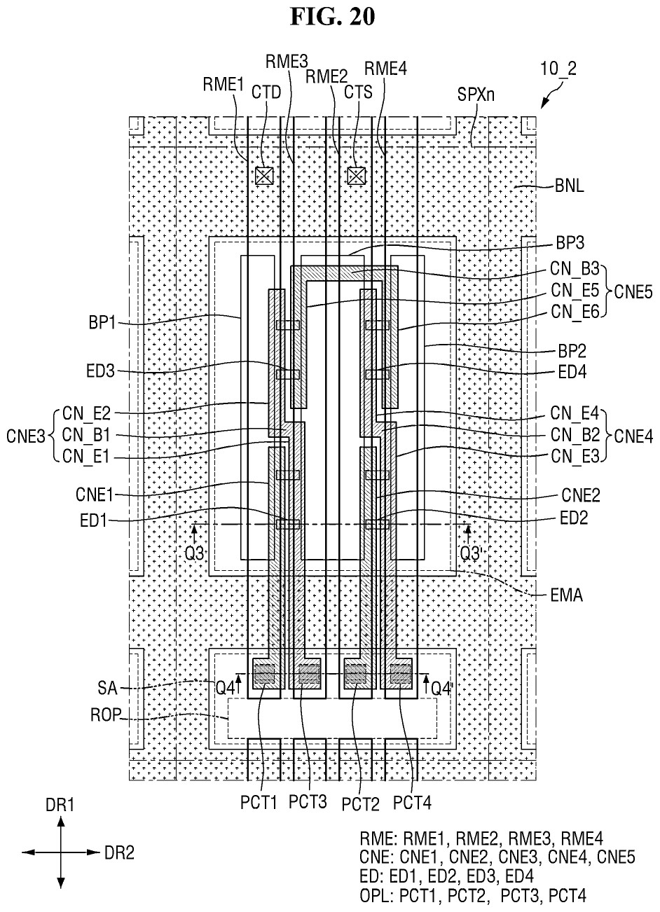

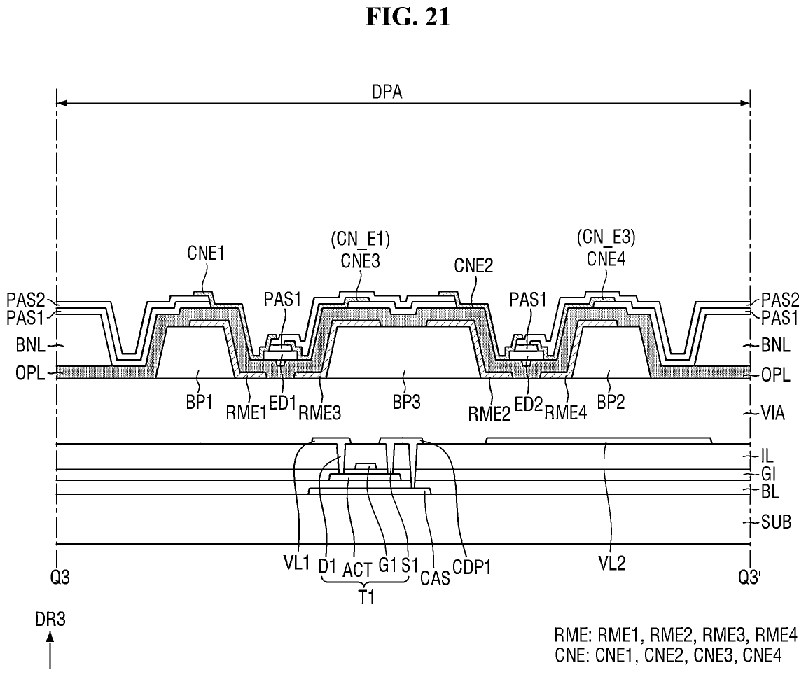

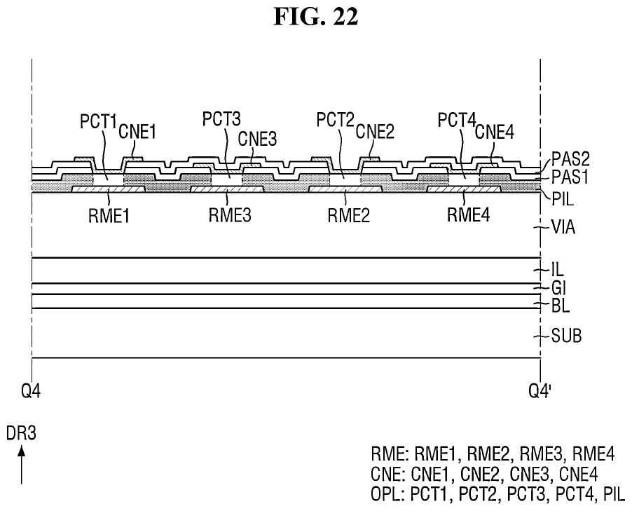

FIG. 20 is a plan view of a subpixel of a display device according to another embodiment of the present disclosure. FIG. 21 is a cross-sectional view taken along line Q3-Q3′ of FIG. 20. FIG. 22 is a cross-sectional view taken along line Q4-Q4′ of FIG. 20. FIG. 21 is a cross-sectional view taken from one end portion to the other end portion of a first light-emitting element ED1 of FIG. 20 and from one end portion to the other end portion of a second light-emitting element ED2 of FIG. 20, and FIG. 22 is a cross-sectional view taken across a plurality of contacts (CT1, CT2, CT3, and CT4) of FIG. 20.

Referring to FIGS. 20 through 22, a display device 10_2 may include a relatively large number of electrodes RME and a relatively large number of connecting electrodes CNE, and the number of light-emitting elements ED in each subpixel SPXn may be increased. The display device 10_2 differs from the display device 10 of FIGS. 4 through 6 in bank patterns (BP1, BP2, and BP3) and the patterns of arrangement of the electrodes RME and the connecting electrodes CNE in each subpixel SPXn. The display device 10_2 will hereinafter be described, focusing mainly on the differences with the display device 10.

The bank patterns (BP1, BP2, and BP3) may include first and second bank patterns BP1 and BP2 and may further include a third bank pattern BP3, which is provided between the first and second bank patterns BP1 and BP2. The first bank pattern BP1 may be on the left side of the center of an emission area EMA of a subpixel SPXn (as shown in FIG. 20, for example), the second bank pattern BP2 may be on the right side of the center of the emission area EMA, and the third bank pattern BP3 may be in the middle of the emission area EMA. The width, in a second direction DR2, of the third bank pattern BP3 may be greater than the widths, in the second direction DR2, of each of the first and second bank patterns BP1 and BP2. The distance, in the second direction DR2, between the bank patterns (BP1, BP2, and BP3) may be greater than the distance between electrodes RME. Accordingly, the electrodes RME may not overlap at least in part with the bank patterns (BP1, BP2, and BP3).

The electrodes RME may include first and second electrodes RME1 and RME2 and may further include third and fourth electrodes RME3 and RME4.

The third electrode RME3 may be between the first and second electrodes RME1 and RME2, and the fourth electrode RME4 may be spaced apart from the third electrode RME3 in the second direction DR2 with the second electrode RME2 interposed therebetween. The electrodes RME may be arranged in the order of the first, third, second, and fourth electrodes RME1, RME3, RME2, and RME4 in a left-to-right direction (as shown in FIG. 20, for example).

The electrodes RME may extend from the emission area EMA to a subarea SA across a bank BNL. The first and second electrodes RME1 and RME2 may be connected (e.g., electrically and/or physically coupled) to a third conductive layer therebelow through electrode contact holes (CTD and CTS). The third and fourth electrodes RME3 and RME4 may not be directly connected to the third conductive layer and may be electrically connected (e.g., electrically coupled) to the first and second electrodes RME1 and RME2 through light-emitting elements ED and connecting electrodes CNE. The first and second electrodes RME1 and RME2 may be first-type electrodes directly connected to the third conductive layer through the electrode contact holes (CTD and CTS), and the third and fourth electrodes RME3 and RME4 may be second-type electrodes not connected directly to the third conductive layer. The second-type electrodes may provide electrical connections for the light-emitting elements ED together with the connecting electrodes CNE.

A plurality of light-emitting elements ED may be positioned between the bank patterns (BP1, BP2, and BP3) and/or between different electrodes RME. Some of the light-emitting elements ED may be between the first and third bank patterns BP1 and BP3, and the other light-emitting elements ED may be between the second and third bank patterns BP2 and BP3. In one example, the light-emitting elements ED may include first light-emitting elements ED1 and third light-emitting elements ED3, which are between the first and third bank patterns BP1 and BP3, and second light-emitting elements ED2 and fourth light-emitting elements ED4, which are between the second and third bank patterns BP2 and BP3. The first light-emitting elements ED1 and the third light-emitting elements ED3 may be on the first and third electrodes RME1 and RME3, and the second light-emitting elements ED2 and the fourth light-emitting elements ED4 may be on the second and fourth electrodes RME2 and RME4. The first light-emitting elements ED1 and the second light-emitting elements ED2 may be in a lower portion of the emission area EMA and/or adjacent to the subarea SA, and the third light-emitting elements ED3 and the fourth light-emitting elements ED4 may be in an upper portion of the emission area EMA. However, the light-emitting elements ED may be classified not by their locations, but by their relations to the connecting electrodes CNE. The light-emitting elements ED may be connected to different sets of connecting electrodes CNE depending on the pattern of arrangement of the connecting electrodes CNE, and may be classified into different types (or kinds) of light-emitting elements ED according to which of the connecting electrodes CNE they are in contact with.

The organic layer OPL may be provided in (e.g., on) the entire surface of the subpixel SPXn and may include conductive regions PCT and an insulating region PIL. The conductive regions PCT may not overlap with, and not be positioned in, the emission area EMA, and may overlap with, and be positioned in, the subarea SA. The insulating region PIL may be in the emission area EMA and the subarea SA.

The conductive regions PCT may include first, second, third, and fourth conductive regions PCT1, PCT2, PCT3, and PCT4, which are in the subarea SA. The first, second, third, and fourth conductive regions PCT1, PCT2, PCT3, and PCT4 may be spaced apart from one another in the second direction DR2 and may be arranged in the order of the first, third, second, and fourth conductive regions PCT1, PCT3, PCT2, and PCT4.

The first conductive region PCT1 may be in the overlapping area of the first electrode RME1 and a first connecting electrode CNE1, and may overlap with the first electrode RME1 and the first connecting electrode CNE1. As a first surface of the first conductive region PCT1 is in contact with the first electrode RME1 and a second surface of the first conductive region PCT1 that is opposite to the first surface of the first conductive region PCT1 is in contact with the first connecting electrode CNE1, the first conductive region PCT1 may electrically connect (e.g., electrically couple) the first electrode RME1 and the first connecting electrode CNE1. The second conductive region PCT2 may be in the overlapping area of the second electrode RME2 and a second connecting electrode CNE2, and may overlap with the second electrode RME2 and the second connecting electrode CNE2. As a first surface of the second conductive region PCT2 is in contact with the second electrode RME2 and a second surface of the second conductive region PCT2 that is opposite to the first surface of the second conductive region PCT2 is in contact with the second connecting electrode CNE2, the second conductive region PCT2 may electrically connect (e.g., electrically couple) the second electrode RME2 and the second connecting electrode CNE2. The third conductive region PCT3 may be in the overlapping area of the third electrode RME3 and a third connecting electrode CNE3, and may overlap with the third electrode RME3 and the third connecting electrode CNE3. As a first surface of the third conductive region PCT3 is in contact with the third electrode RME3 and a second surface of the third conductive region PCT3 that is opposite to the first surface of the third conductive region PCT3 is in contact with the third connecting electrode CNE3, the third conductive region PCT3 may electrically connect (e.g., electrically couple) the third electrode RME3 and the third connecting electrode CNE3. The fourth conductive region PCT4 may be in the overlapping area of the fourth electrode RME4 and a fourth connecting electrode CNE4, and may overlap with the fourth electrode RME4 and the fourth connecting electrode CNE4. As a first surface of the fourth conductive region PCT4 is in contact with the fourth electrode RME4 and a second surface of the fourth conductive region PCT4 that is opposite to the first surface of the fourth conductive region PCT4 is in contact with the fourth connecting electrode CNE4, the fourth conductive region PCT4 may electrically connect (e.g., electrically couple) the fourth electrode RME4 and the fourth connecting electrode CNE4.

The connecting electrodes CNE may include the first and second connecting electrodes CNE1 and CNE2, which are on the first and second electrodes RME1 and RME2, and the third, fourth, and fifth connecting electrodes CNE3, CNE4, and CNE5, which are each on multiple electrodes RME.

In the embodiments of FIGS. 20-22, unlike in the embodiment of FIGS. 4 through 6, the first and second connecting electrodes CNE1 and CNE2 may have a relatively small length in a first direction DR1. The first and second connecting electrodes CNE1 and CNE2 may be on the lower side relative to the center of the emission area EMA. The first and second connecting electrodes CNE1 and CNE2 may be positioned in and across the emission area and the subarea SA and may be in contact with the first and second electrodes RME1 and RME2 through the first and second conductive regions PCT1 and PCT2 of the organic layer OPL, which are formed in the subarea SA.

The third connecting electrode CNE3 may include a first extension CN_E1, which is on the third electrode RME3, a second extension CN_E2, which is on the first electrode RME1, and a first connector CN_B1, which connects (e.g., physically couples) the first and second extensions CN_E1 and CN_E2. The first extension CN_E1 may be spaced apart from, and face, the first connecting electrode CNE1 in the second direction DR2, and the second extension CN_E2 may be spaced apart from the first connecting electrode CNE1 in the first direction DR1. The first extension CN_E1 may be in a lower portion of the emission area EMA, and the second extension CN_E2 may be in an upper portion of the emission area EMA. The first extension CN_E1 may be positioned in and across the emission area EMA and the subarea SA and may be connected (e.g., electrically and/or physically coupled) to the third electrode RME3 through the third conductive region PCT3 of the organic layer OPL, which is formed in the subarea SA. The first connector CN_B1 may be in the middle portion of the emission area EMA, over the first and third electrodes RME1 and RME3. The third connecting electrode CNE3 may generally extend in the first direction DR1, be bent in the second direction DR2, and extend again in the first direction DR1.

The fourth connecting electrode CNE4 may include a third extension CN_E3, which is on the fourth electrode RME4, a fourth extension CN_E4, which is on the second electrode RME2, and a second connector CN_B2, which connects (e.g., physically couples) the third and fourth extensions CN_E3 and CN_E4. The third extension CN_E3 may be spaced apart from, and face, the second connecting electrode CNE2 in the second direction DR2, and the fourth extension CN_E4 may be spaced apart from the second connecting electrode CNE2 in the first direction DR1. The third extension CN_E3 may be in the lower portion of the emission area EMA, and the fourth extension CN_E4 may be in the upper portion of the emission area EMA. The third extension CN_E3 may be positioned in and across the emission area EMA and the subarea SA and may be connected (e.g., electrically and/or physically coupled) to the fourth electrode RME4 through the fourth conductive region PCT4 of the organic layer OPL, which is formed in the subarea SA. The second connector CN_B2 may be in the middle portion of the emission area EMA, over the second and fourth electrodes RME2 and RME4. The fourth connecting electrode CNE4 may generally extend in the first direction DR1, be bent in the second direction DR2, and extend again in the first direction DR1.

The fifth connecting electrode CNE5 may include a fifth extension CN_E5, which is on the third electrode RME3, a sixth extension CN_E6, which is on the fourth electrode RME4, and a third connector CN_B3, which connects (e.g., physically couples) the fifth and sixth extensions CN_E5 and CN_E6. The fifth extension CN_E5 may be spaced apart from, and face, the second extension CN_E2 of the third connecting electrode CNE3 in the second direction DR2, and the sixth extension CN_E6 may be spaced apart from, and face, the fourth extension CN_E4 of the fourth connecting electrode CNE4 in the second direction DR2. The fifth and sixth extensions CN_E5 and CN_E6 may be in the upper portion of the emission area EMA, and the third connector CN_B3 may be over the second, third, and fourth electrodes RME2, RME3, and RME4. The fifth connecting electrode CNE5 may surround the fourth extension CN_E4 of the fourth connecting electrode CNE4 in a plan view.

The first and second connecting electrodes CNE1 and CNE2 may be first-type connecting electrodes connected (e.g., electrically and/or physically coupled) to the first and second electrodes RME1 and RME2, which are directly connected (e.g., physically coupled) to the third conductive layer, the third and fourth connecting electrodes CNE3 and CNE4 may be second-type connecting electrodes connected (e.g., electrically and/or physically coupled) to the third and fourth electrodes RME3 and RME4, which are not directly connected (e.g., not physically coupled) to the third conductive layer, and the fifth connecting electrode CNE5 may be a third-type connecting electrode connected to none of the electrodes RME.

As already mentioned above, the light-emitting elements ED may be classified into different types (or kinds) of light-emitting elements depending on which of the connecting electrodes CNE they are connected to.

The first end portions of the first light-emitting elements ED1 and the first end portions of the second light-emitting elements ED2 may be in contact with the first-type connecting electrodes, and the second end portions of the first light-emitting elements ED1 and the second end portions of the second light-emitting elements ED2 may be in contact with the second-type connecting electrodes. The first light-emitting elements ED1 may be in contact with the first and third connecting electrodes CNE1 and CNE3, and the second light-emitting elements ED2 may be in contact with the second and fourth connecting electrodes CNE2 and CNE4. The first end portions of the third light-emitting elements ED3 and the first end portions of the fourth light-emitting elements ED4 may be in contact with the second-type connecting electrodes, and the second end portions of the third light-emitting elements ED3 and the second end portions of the fourth light-emitting elements ED4 may be in contact with the third-type connecting electrode. The third light-emitting elements ED3 may be in contact with the third and fifth connecting electrodes CNE3 and CNE5, and the fourth light-emitting elements ED4 may be in contact with the fourth and fifth connecting electrodes CNE4 and CNE5.

The light-emitting elements ED may be connected in series by the connecting electrodes CNE. As the display device 10 includes a considerable number of light-emitting elements ED in the subpixel SPXn and can form serial connections between the light-emitting elements ED, the amount of light emitted per unit area can be further increased.

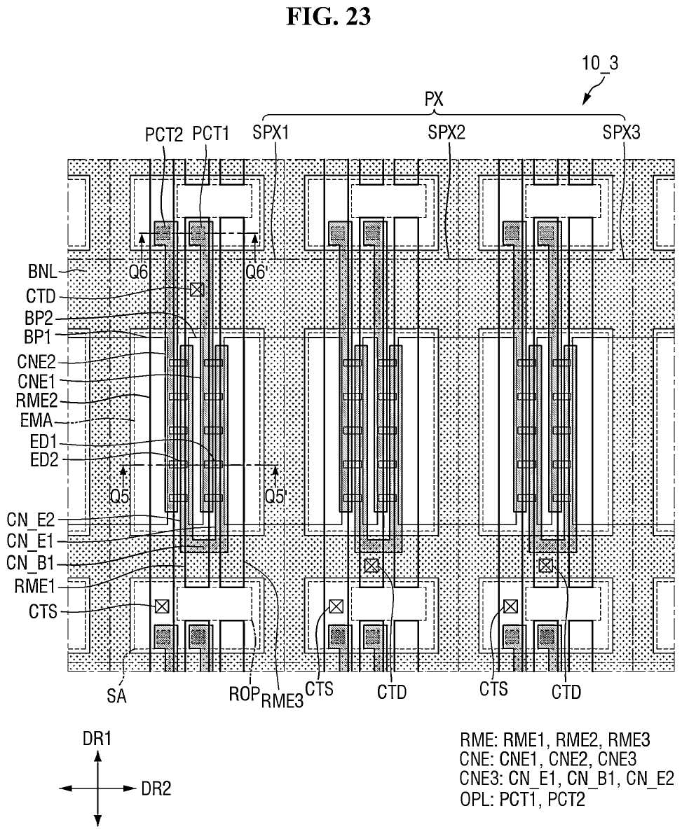

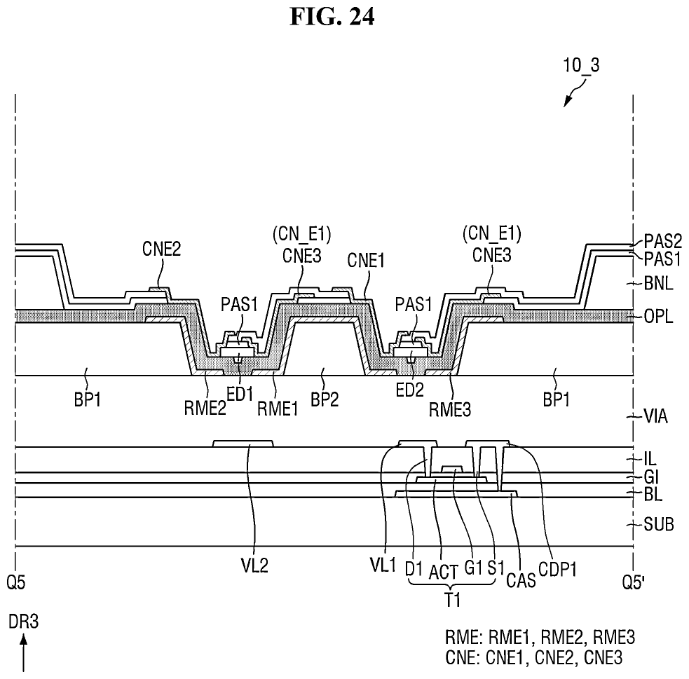

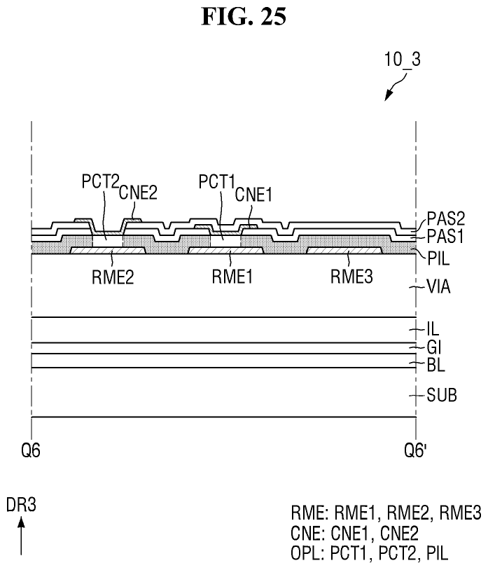

FIG. 23 is a plan view of a pixel of a display device according to one or more other embodiments of the present disclosure. FIG. 24 is a cross-sectional view taken along line Q5-Q5′ of FIG. 23. FIG. 25 is a cross-sectional view taken along line Q6-Q6′ of FIG. 23. FIG. 24 is a cross-sectional view taken from one end portion to the other end portion of a first light-emitting element ED1 of FIG. 20 and from one end portion to the other end portion of a second light-emitting element ED2 of FIG. 23, and FIG. 25 is a cross-sectional view taken across conductive regions PCT of an organic layer OPL of FIG. 23.

Referring to FIGS. 23-25, a display device 10 may differ from the display device of FIGS. 4-6 and FIGS. 20-22 in the structures of electrodes RME, connecting electrodes CNE, and bank patterns (BP1 and BP2).

Bank patterns (BP1 and BP2) of each subpixel SPXn may have different widths in a second direction DR2, and one of the bank patterns (BP1 and BP2) may be positioned in and across a pair of adjacent subpixels SPXn in the second direction DR2. In one example, the bank patterns (BP1 and BP2) may include first bank patterns BP1, which are positioned in and across emission areas EMA of multiple subpixels SPXn, and a second bank pattern BP2, which is positioned between the first bank patterns BP1.

The second bank pattern BP2 may be in the middle portion of an emission area EMA of the corresponding subpixel SPXn, and the first bank patterns BP1 may be spaced apart from each other with the second bank pattern BP2 interposed therebetween. The first bank patterns BP1 and the second bank pattern BP2 may be arranged alternately with each other in the second direction DR2. Light-emitting elements ED may be provided in the gaps between the first bank patterns BP1 and the second bank pattern BP2.

The first bank patterns BP1 and the second bank pattern BP2 may have the same length in a first direction DR1 and different widths in the second direction DR2. Portions of a bank BNL that extend in the first direction DR1 may overlap with the first bank patterns BP1 in a thickness direction. The bank patterns (BP1 and BP2) may be arranged on the entire surface of a display area DPA as island patterns.

The electrodes RME includes first, second, and third electrodes RME1, RME2, and RME3. The first electrode RME1 may be in the middle potion of the emission area EMA, the second electrode RME2 may be on the left side of the first electrode RME1, and the third electrode RME3 may be on the right side of the first electrode RME1.

The first electrode RME1 may be on the second bank pattern BP2, and parts of each of the second and third electrodes RME2 and RME3 may be on different first bank patterns BP1. Each of the electrodes RME may be positioned on an inclined side surface of one of the bank patterns (BP1 and BP2). The first electrode RME1 may have a larger width in the second direction DR2 than the second bank pattern BP2, and the second and third electrodes RME2 and RME3 may have a smaller width in the second direction DR2 than the first bank patterns BP1.

The first and third electrodes RME1 and RME3 may extend in the first direction DR1 and may be spaced apart from first and third electrodes RME1 and RME3 of a neighboring (in the first direction DR1) subpixel SPXn, in a separation part ROP. In contrast, the second electrode RME2 may extend in the first direction DR1 across multiple subpixels SPXn arranged in the first direction DR1.

The first electrode RME1 may be connected (e.g., electrically and/or physically coupled) to a third conductive layer through a first electrode contact hole CTD, which is formed in an area that overlaps with the bank BNL. A first electrode RME1 of a first subpixel SPX1 may be in contact with the third conductive layer through a first electrode contact hole CTD, which penetrates a via layer VIA in an area that overlaps with the bank BNL in an upper portion of an emission area EMA of the first subpixel SPX1. The first electrodes RME1 of second and third subpixels SPX2 and SPX3 may be connected (e.g., electrically and/or physically coupled) to the third conductive layer through first electrode contact holes CTD, which penetrate the via layer VIA in areas that overlap with the bank BNL in lower portions of emission areas EMA of the second and third subpixels SPX2 and SPX3. The locations of first electrode contact holes CTD of different subpixels SPXn may differ depending on the structure of the third conductive layer in each of the different subpixels SPXn.

The second electrode RME2 may be connected (e.g., electrically and/or physically coupled) to a second voltage line VL2 through a second electrode contact hole CTS, which penetrates the via layer VIA in a subarea SA below the emission area EMA.

A plurality of light-emitting elements ED may be provided on different electrodes RME between different bank patterns (BP1 and BP2). The light-emitting elements ED may include first light-emitting elements ED1, which have both end portions thereof on the first and third electrodes RME1 and RME3, respectively, and second light-emitting elements ED2, which have both end portions thereof on the first and second electrodes RME1 and RME2, respectively. The first light-emitting elements ED1 may be on the right side of the first electrode RME1, and the second light-emitting elements ED2 may be on the left side of the first electrode RME1 (as shown in, for example, FIG. 23).

In one or more embodiments, an organic layer OPL may be on the entire surface of each subpixel SPXn and may include conductive regions PCT and an insulating region PIL. The conductive regions PCT may not overlap with, and not be located in, the emission area EMA of each subpixel SPXn and may overlap with, and be located in, the subarea SA of each subpixel SPXn. The insulating region PIL may be in the emission area EMA and the subarea SA of each subpixel SPXn.

The conductive regions PCT may include first and second conductive regions PCT1 and PCT2, which are in the subarea SA of each subpixel SPXn. The first and second conductive regions PCT1 and PCT2 may be spaced apart from each other in the second direction DR2.

The first conductive region PCT1 may be in the overlapping area of the first electrode RME1 and a first connecting electrode CNE1, and may overlap with the first electrode RME1 and the first connecting electrode CNE1. As a first surface of the first conductive region PCT1 is in contact (e.g., physical contact) with the first electrode RME1 and a second surface of the first conductive region PCT1 that is opposite to the first surface of the first conductive region PCT1 is in contact (e.g., physical contact) with the first connecting electrode CNE1, the first conductive region PCT1 may electrically connect (e.g., electrically couple) the first electrode RME1 and the first connecting electrode CNE1. The second conductive region PCT2 may be in the overlapping area of the second electrode RME2 and a second connecting electrode CNE2 and may overlap with the second electrode RME2 and the second connecting electrode CNE2. As a first surface of the second conductive region PCT2 is in contact (e.g., physical contact) with the second electrode RME2 and a second surface of the second conductive region PCT2 that is opposite to the first surface of the second conductive region PCT2 is in contact (e.g., physical contact) with the second connecting electrode CNE2, the second conductive region PCT2 may electrically connect (e.g., electrically couple) the second electrode RME2 and the second connecting electrode CNE2. The insulating region PIL may be in the entire organic layer OPL except for the conductive regions PCT.

The connecting electrodes CNE may include the first and second connecting electrodes CNE1 and CNE2, which are first-type connecting electrodes, and a third connecting electrode CNE3, which is a second-type connecting electrode.

The first connecting electrode CNE1 may extend in the first direction DR1 and may be on the first electrode RME1. Portion of the first connecting electrode CNE1 on the second bank pattern BP2 may overlap with the first electrode RME1 and may extend in the first direction DR1 from the first electrode RME1 beyond the bank BNL to be positioned in a subarea SA of another subpixel SPXn above the emission area EMA of the corresponding subpixel SPXn. The first connecting electrode CNE1 may be in contact (e.g., electrical contact) with the first electrode RME1 through the first conductive region PCT1 of the organic layer OPL in the subarea SA of the corresponding subpixel SPXn.

The second connecting electrode CNE2 may extend in the first direction DR1 and may be on the second electrode RME2. Portion of the second connecting electrode CNE2 on the second bank pattern BP2 may overlap with the second electrode RME2 and may extend in the first direction DR1 from the second electrode RME2 beyond the bank BNL to be positioned in a subarea SA of another subpixel SPXn above the emission area EMA of the corresponding subpixel SPXn. The second connecting electrode CNE2 may be in contact (e.g., electrical contact) with the second electrode RME2 through the second conductive region PCT2 of the organic layer OPL in the subarea SA of the corresponding subpixel SPXn.

The third connecting electrode CNE3 may include first and second extensions CN_E1 and CN_E2, which extend in the first direction DR1, and a first connector CN_B1, which connects the first and second extensions CN_E1 and CN_E2. The first extension CN_E1 may be on the third electrode RME3, in the emission area EMA, and the second extension CN_E2 may be on the first electrode RME1, in the emission area EMA. The first connector CN_B1 may extend in the second direction DR2 on portion of the bank BNL below the emission area EMA and may connect the first and second extensions CN_E1 and CN_E2. The third connecting electrode CNE3 may be in the emission area EMA and on the bank BNL and may not be connected to the third electrode RME3.

The third electrode RME3 may be completely covered by the organic layer OPL. The top surface of the third electrode RME3 may not be exposed in the subarea SA, and the third electrode RME3 may be arranged in a floated state where the third electrode RME3 is not electrically connected to the connecting electrodes CNE and the light-emitting elements ED. The first light-emitting elements ED1 and the second light-emitting elements ED2 may be connected in series only through the third connecting electrode CNE3.

The third electrode RME3 may remain floated not to be connected to the connecting electrodes CNE, as illustrated in FIG. 23, but may be connected to another electrode RME adjacent thereto. For example, the third electrode RME3 may be connected to a second electrode RME2 of a neighboring subpixel SPXn adjacent to the corresponding subpixel SPXn in the second direction DR2, and a second power supply voltage may be applied to the third electrode RME3. Even if the second power supply voltage is applied to the third electrode RME3, the second power supply voltage may not affect the emission of light by the light-emitting elements ED because the third electrode RME3 is not connected to the connecting electrodes CNE. In this example, the third electrode RME3 may branch off of the second electrode RME2 of the neighboring subpixel SPXn, and only the first electrode RME2 may be separated in the separation part ROP of the subarea SA of the corresponding subpixel SPXn.

Embodiments of the present disclosure will hereinafter be described in further detail by way of the following production and experimental examples.

### Production Example 1: Fabrication of PEDOT:PSS Organic Layer

Sample #1 was obtained by applying PEDOT:PSS onto a substrate to a thickness of 3500 Å and performing thermal treatment to form an organic layer. Photoresist patterns were formed on the organic layer of sample #1, and a sodium hypochlorite etchant was sprayed for 45 seconds to form conductive regions and an insulating region in the organic layer. Sample #2 was obtained by forming the insulating region to have a width of 3 μm, sample #3 was obtained by forming the insulating region to have a width of 5 μm, and sample #4 was obtained by forming the insulating region to have a width of 10 μm.

### Experimental Example 1: Images of Organic Layers and Measurement of Surface Roughness

Samples #2, #3, and #4 were observed with an optical microscope, and atomic force microscopy (AFM) measurement was performed on 10 μm×10 μm areas of samples #1 and #2.

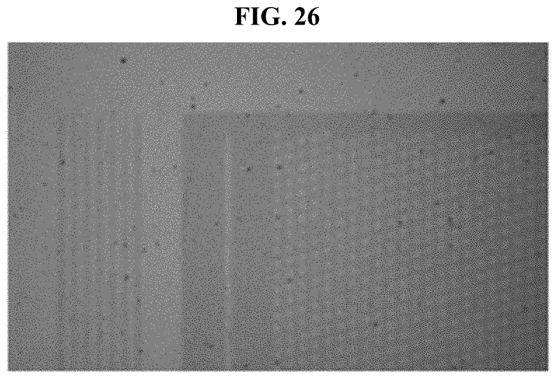

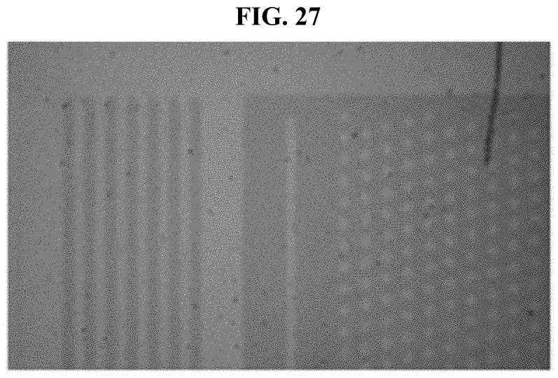

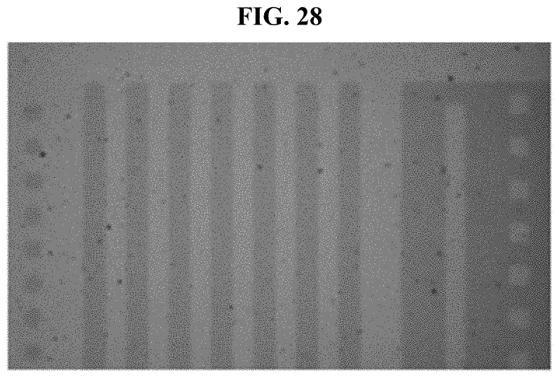

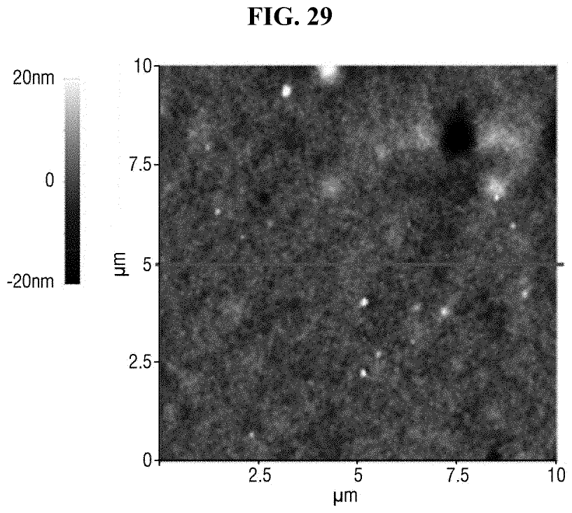

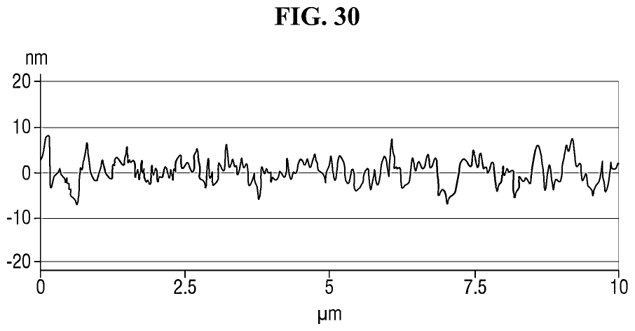

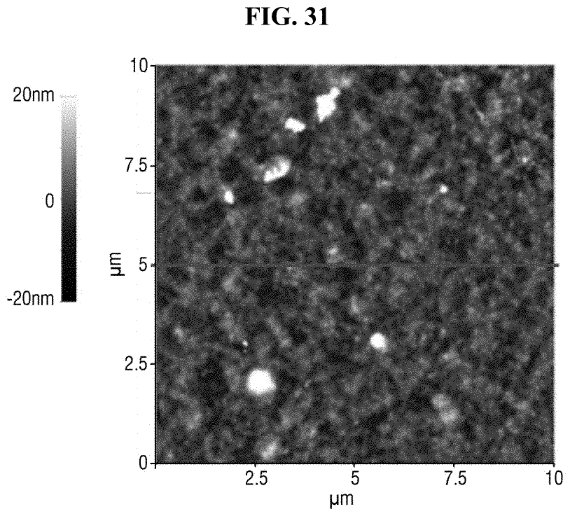

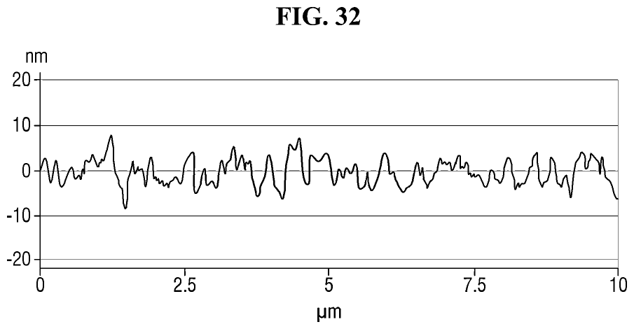

FIG. 26 is an optical microscope image of sample #2. FIG. 27 is an optical microscope image of sample #3. FIG. 28 is an optical microscope image of sample #4. FIG. 29 is an AFM image of sample #1. FIG. 30 is a graph showing AFM measurements from sample #1. FIG. 31 is an AFM image of sample #2. FIG. 32 is a graph showing AFM measurements from sample #2.

FIGS. 26-28 show that conductive regions, which appear relatively dark, and an insulating region, which appears relatively bright, were formed clearly in samples #2, #3, and #4.

Also, FIGS. 29 through 32 show that samples #1 and #2 have a surface roughness of about 3.23±0.03 nm and about 3.63±0.03 nm, respectively, which means that surface roughness is greater after exposure to the etchant than before exposure.

### Production Example 2: Fabrication of PEDOT:PSS Organic Layer

Sample #5 was obtained by applying PEDOT:PSS onto a substrate to a thickness of 3500 Å to form an organic layer. Sample #6 was obtained by applying PEDOT:PSS onto a substrate to a thickness of 3500 Å and performing thermal treatment for 1100 seconds at a temperature of 220° C. to form an organic layer.

### Experimental Example 2: Measurement of Transmittances and Surface Roughnesses of Organic Layer Samples

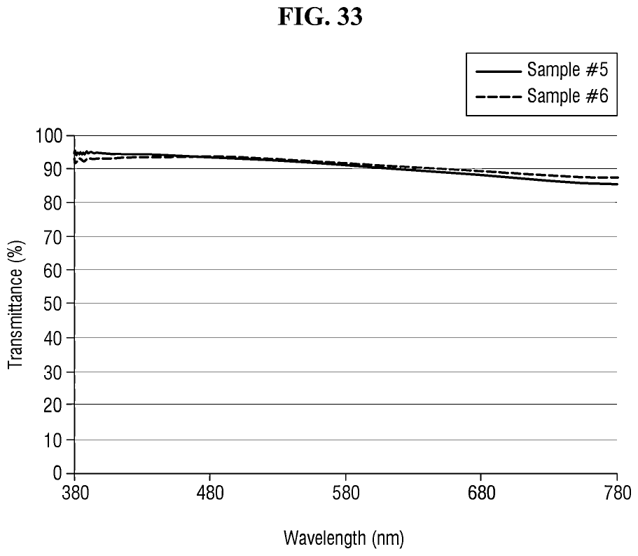

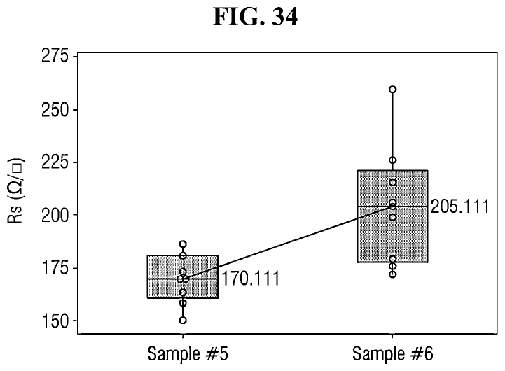

The transmittances of samples #5 and #6 for a wavelength range of 380 nm to 780 nm were measured, and the surface resistivities of samples #5 and #6 were measured. The results are as shown in FIGS. 33 and 34 and Table 1 below.

FIG. 33 is a graph showing the transmittances of samples #5 and #6 in accordance with wavelength. FIG. 34 is a graph showing the surface resistivities of samples #5 and #6. Referring to FIG. 34, a value next to each rectangular bar represents average surface roughness.

TABLE 1

| | Transmittance (%) | | | | |
|---|---|---|---|---|---|
| | Average | | | | Surface |
| | Transmittance | | | | Resistivity |
| | (380~780 nm) | 450 nm | 550 nm | 650 nm | (Ω/□) |
| Sample #5 | 90.65 | 93.84 | 91.91 | 88.94 | 170.1 ± 11.61 |
| Sample #6 | 91.17 | 93.44 | 92.42 | 90.01 | 205.1 ± 27.89 |

Referring to FIGS. 33 and 34 and Table 1, sample #5 has an average transmittance of 90% or greater and a surface resistivity of about 170Ω/□, and sample #6 has an average transmittance of 91% or greater and a surface resistivity of about 205Ω/□.

The results above show that as all the sample PEDOT:PSS organic layers have a high transmittance of 90% or greater regardless of whether they have been through thermal treatment, they would not cause nearly any loss of light through reflection even when formed on the electrodes of a display device. Also, it is believed that as the sample PEDOT:PSS organic layers have a surface resistivity of about 205Ω/□, they could form ohmic contacts with the electrodes and/or the connecting electrodes of a display device.

In concluding the detailed description, those skilled in the art will appreciate that many variations and modifications can be made to the embodiments described herein without substantially departing from the principles of the present disclosure as set forth in the following claims and their equivalents. Therefore, the disclosed embodiments of the present disclosure are used in a generic and descriptive sense only and not for purposes of limitation.

What is claimed is:

1. A display device comprising:
a first electrode and a second electrode, each extending in one direction on a substrate, the first and second electrodes being spaced apart from each other;
an organic layer on the first and second electrodes, the organic layer comprising a plurality of conductive regions and an insulating region;
light-emitting elements on the organic layer and on the first and second electrodes; and
a first connecting electrode coupled to first end portions of the light-emitting elements and one of the plurality of conductive regions, and a second connecting electrode coupled to second end portions of the light-emitting elements and another one of the plurality of conductive regions,
wherein:
the organic layer comprises PEDOT:PSS, and
a surface roughness of the insulating region is greater than a surface roughness of the plurality of conductive regions.

2. The display device of claim 1, wherein the plurality of conductive regions comprise a first conductive region, which overlaps with the first electrode and the first connecting electrode, and a second conductive region, which overlaps with the second electrode and the second connecting electrode.

3. The display device of claim 2, wherein
a first surface of the first conductive region is in contact with the first electrode,
a second surface of the first conductive region is in contact with the first connecting electrode,
a first surface of the second conductive region is in contact with the second electrode, and
a second surface of the second conductive region is in contact with the second connecting electrode.

4. The display device of claim 1, wherein the insulating region is a region of the organic layer other than the conductive regions.

5. The display device of claim 1, wherein
the plurality of conductive regions comprise a compound represented by Formula 1, and
the insulating region comprises a compound represented by Formula 2:

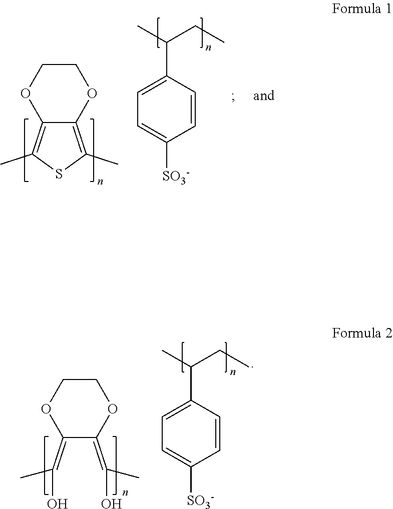

6. The display device of claim 1, wherein
the substrate comprises a display area and a pad area,
the first electrode, the second electrode, the light-emitting elements, the first connecting electrode, and the second connecting electrode are in the display area, and
the organic layer is in the display area and the pad area.

7. The display device of claim 6, wherein the pad area comprises a pad electrode on the substrate, a pad electrode upper layer on the pad electrode, the organic layer on the pad electrode upper layer, and a pad electrode capping layer on the organic layer.

8. The display device of claim 7, wherein
the pad electrode upper layer comprises the same material as the first electrode or the second electrode,
the pad electrode capping layer comprises the same material as the first connecting electrode or the second connecting electrode, and
the organic layer further comprises a third conductive region, which overlaps with the pad electrode upper layer.

9. The display device of claim 8, wherein
a first surface of the third conductive region is in contact with the pad electrode upper layer, and
a second surface of the third conductive region is in contact with the pad electrode capping layer.

10. The display device of claim 1, wherein
the organic layer further comprises conductive particles, and
the conductive particles are in an amount of 1 wt % to 10 wt % with respect to 100 wt % of the organic layer.

11. The display device of claim 10, wherein the conductive particles comprise at least one selected from among a metal, silver nanowires, and graphene.

12. A display device comprising:
a first electrode and a second electrode, each extending in one direction on a substrate, the first and second electrodes being spaced apart from each other;
an organic layer on the first and second electrodes, the organic layer comprising a plurality of conductive regions and an insulating region;
light-emitting elements on the organic layer and on the first and second electrodes; and
a first connecting electrode coupled to first end portions of the light-emitting elements and to one of the plurality of conductive regions and a second connecting electrode coupled to second end portions of the light-emitting elements and to another one of the plurality of conductive regions,
wherein:
the plurality of conductive regions of the organic layer comprise a compound represented by Formula 1, and
the insulating region of the organic layer comprises a compound represented by Formula 2:

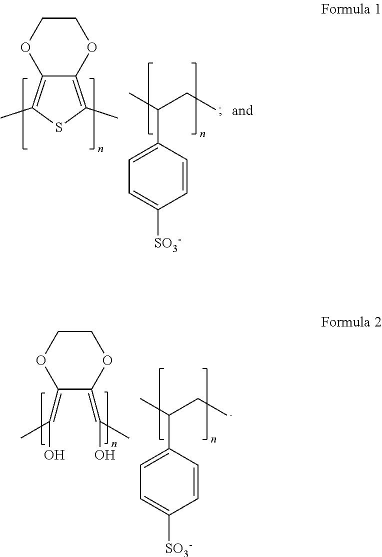

13. The display device of claim 12, wherein a surface roughness of the insulating region is greater than a surface roughness of the plurality of conductive regions.

14. The display device of claim 12, further comprising:
a bank on the organic layer, the bank comprising an emission area, in which the light-emitting elements are provided, and a subarea spaced apart from the emission area.

15. The display device of claim 14, wherein the plurality of conductive regions are in the emission area or the subarea.

16. The display device of claim 15, wherein the plurality of conductive regions comprise a first conductive region, which overlaps with the first electrode and the first connecting electrode, and a second conductive region, which overlaps with the second electrode and the second connecting electrode.

17. The display device of claim 12, wherein
the organic layer further comprises conductive particles, and
the conductive particles are in an amount of 1 wt % to 10 wt % with respect to 100 wt % of the organic layer.

18. The display device of claim 17, wherein the conductive particles comprise at least one selected from among a metal, silver nanowires, and graphene.

19. The display device of claim 12, further comprising:
a first bank pattern between the substrate and the first electrode; and
a second bank pattern between the substrate and the second electrode,
wherein the plurality of conductive regions overlap with the first and second bank patterns.

20. The display device of claim 12, wherein each of the light-emitting elements comprises a first semiconductor layer doped with an n-type dopant, a second semiconductor layer doped with a p-type dopant, a light-emitting layer between the first and second semiconductor layers, and an insulating film around outer surfaces of the first semiconductor layer, the second semiconductor layer, and the light-emitting layer.
